(19) United States
(12) Patent Application Publication
(10) Pub. No.: US 2024/0203876 A1
(43) Pub. Date: Jun. 20, 2024

(54) SEMICONDUCTOR MEMORY DEVICE

(71) Applicant: Kioxia Corporation, Tokyo (JP)

(72) Inventors: Hidenobu NAGASHIMA, Yokkaichi Mie (JP); Tatsuya ISHIDA, Yokkaichi Mie (JP); Yusuke OKUMURA, Yokkaichi Mie (JP); Toru MATSUDA, Yokkaichi Mie (JP); Akiko NOMACHI, Yokkaichi Mie (JP)

(73) Assignee: Kioxia Corporation, Tokyo (JP)

(21) Appl. No.: 18/467,773

(22) Filed: Sep. 15, 2023

(30) Foreign Application Priority Data
Dec. 20, 2022 (JP) 2022-203724

(51) Int. Cl. H01L 23/528; G11C 16/04; H10B 43/10; H10B 43/20; H10B 43/35

(52) U.S. Cl. CPC H01L 23/5283; G11C 16/0483; H10B 43/10; H10B 43/20; H10B 43/35

(57) ABSTRACT

According to one embodiment, a semiconductor memory device includes a stacked body including a first and second stacked portions including first and second conductive layers and having first and second end portions stepwise processed, a first and second interlayer insulating layers covering the first and second end portions, a first stopper insulating layer provided at least between the first and second interlayer insulating layers and above the first end portion, including a first portion extending flat above the first end portion, and first contacts penetrating the second interlayer insulating layer, the first portion of the first stopper insulating layer and the first interlayer insulating layer, and connected to different first conductive layers.

### CROSS-REFERENCE TO RELATED APPLICATIONS

This application is based upon and claims the benefit of priority from Japanese Patent Application No. 2022-203724, filed Dec. 20, 2022, the entire contents of which are incorporated herein by reference.

### FIELD

Embodiments described herein relate generally to a semiconductor memory device.

### BACKGROUND

In a three-dimensional nonvolatile semiconductor memory device with a stacked structure in which a plurality of memory cells are vertically stacked, when the number of stacked memory cells increases, it becomes difficult to precisely form contacts connected to lines extending from the memory cells.

### BRIEF DESCRIPTION OF THE DRAWINGS

FIG. 1 is a schematic view illustrating a whole layout of a semiconductor memory device of a first embodiment.

FIG. 2 is a plan pattern diagram schematically illustrating a structure of a memory region and a stairs region of the semiconductor memory device of the first embodiment.

FIG. 3 is a schematic cross-sectional view of the structure of the memory region and the stairs region of the semiconductor memory device of the first embodiment.

FIG. 4 is a schematic cross-sectional view illustrating the structure of the memory region of the semiconductor memory device of the first embodiment.

FIGS. 5A and 5B each are schematic cross-sectional view illustrating the detailed structure of a memory cell portion of the semiconductor memory device of the first embodiment.

FIGS. 6A, 6B, 6C, 6D, 6E, 6F, 6G, 6H, 6I, 6J, 6K, 6L, and 6M each are a schematic cross-sectional view of a part of a manufacturing method of the semiconductor memory device of the first embodiment.

FIG. 7 is a schematic view illustrating a pattern of a contact when an alignment shift occurs in the semiconductor memory device of the first embodiment.

FIG. 8 is a schematic cross-sectional view illustrating a shape of the contact when an alignment shift occurs in the semiconductor memory device of the first embodiment.

FIG. 9 is a plan pattern diagram schematically illustrating a structure of a memory region and a stairs region of a semiconductor memory device of a second embodiment.

FIG. 10 is a schematic cross-sectional view of the structure of the memory region and the stairs region of the semiconductor memory device of the second embodiment.

FIGS. 11A, 11B, 11C, 11D, 11E, 11F, 11G, 11H, 11I, 11J, 11K, 11L, and 11M each are a schematic cross-sectional view of a part of a manufacturing method of the semiconductor memory device of the second embodiment.

FIG. 12 is a plan pattern diagram schematically illustrating a structure of a memory region and a stairs region of a semiconductor memory device of a third embodiment.

FIG. 13 is a schematic cross-sectional view of the structure of the memory region and the stairs region of the semiconductor memory device of the third embodiment.

FIGS. 14A, 14B, 14C, 14D, 14E, 14F, and 14G each are a schematic cross-sectional view of a part of a manufacturing method of the semiconductor memory device of the third embodiment.

FIG. 15 is a plan pattern diagram schematically illustrating a structure of a memory region and a stairs region of a semiconductor memory device of a fourth embodiment.

FIG. 16 is a schematic cross-sectional view of the structure of the memory region and the stairs region of the semiconductor memory device of the fourth embodiment.

FIGS. 17A, 17B, 17C, and 17D each are a schematic cross-sectional view of a part of a manufacturing method of the semiconductor memory device of the fourth embodiment.

### DETAILED DESCRIPTION

In general, according to one embodiment, a semiconductor memory device includes: a stacked body including a first stacked portion including a plurality of first conductive layers stacked to be apart from each other in a first direction and having a first end portion stepwise processed along a second direction crossing the first direction, and a second stacked portion provided on an upper layer side of the first stacked portion, including a plurality of second conductive layers stacked to be apart from each other in the first direction, and having a second end portion arranged beside the first end portion in the second direction and stepwise processed along the second direction; a plurality of pillar structures each including a semiconductor layer extending along the first direction in the stacked body; a first interlayer insulating layer covering the first end portion; a second interlayer insulating layer provided on an upper layer side of the first interlayer insulating layer and covering the second end portion; a first stopper insulating layer provided at least between the first interlayer insulating layer and the second interlayer insulating layer and above the first end portion, including a first portion extending flat along a plane perpendicular to the first direction above the first end portion throughout the first end portion in the second direction, and formed of a material with a main component which is different from that of a material of the first interlayer insulating layer and that of a material of the second interlayer insulating layer; a second stopper insulating layer including at least a first portion provided on an upper layer side of the second interlayer insulating layer and above the second end portion, and formed of a material with a main component which is different from that of the material of the first interlayer insulating layer and that of the material of the second interlayer insulating layer; a plurality of first contacts penetrating the second interlayer insulating layer, the first portion of the first stopper insulating layer and the first interlayer insulating layer, and connected to different first conductive layers, respectively, of the plurality of first conductive layers; and a plurality of second contacts penetrating the first portion of the second stopper insulating layer and the second interlayer insulating layer, and connected to different second conductive layers, respectively, of the plurality of second conductive layers.

Hereinafter, embodiments will be explained with reference to the accompanying drawings.

### First Embodiment

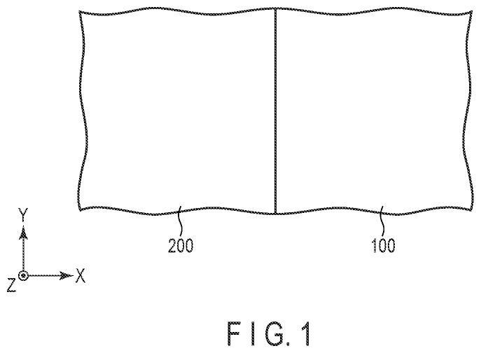

FIG. 1 is a schematic view illustrating a whole layout of a nonvolatile semiconductor memory device of a first embodiment. Note that directions X, Y, and Z of FIG. 1 and other figures are directions crossing each other. Specifically, directions X, Y, and Z are orthogonal to each other.

As shown in FIG. 1, a semiconductor memory device of the present embodiment includes a memory region 100 and a stairs region 200, and the memory region 100 and the stairs region 200 are provided on the same semiconductor substrate.

The memory region 100 includes a three-dimensional NAND nonvolatile memory cell array. Specifically, a NAND string is structured with a plurality of memory cells and a plurality of select transistors arranged in a direction vertical to the semiconductor substrate (direction Z).

The stairs region 200 is provided to be adjacent to the memory region 100. As described later, a plurality of contacts are provided in the stairs region 200 to supply signals to the memory region 100.

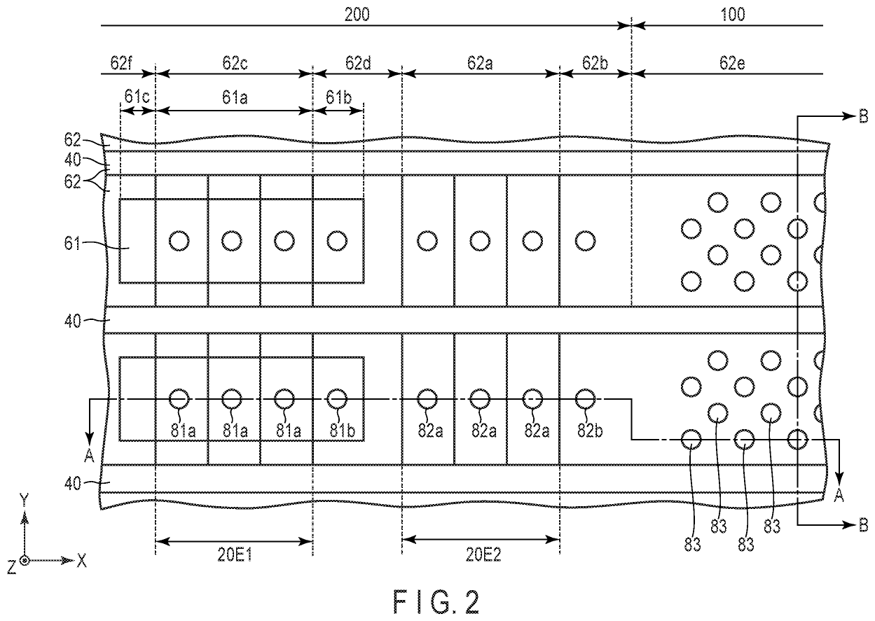

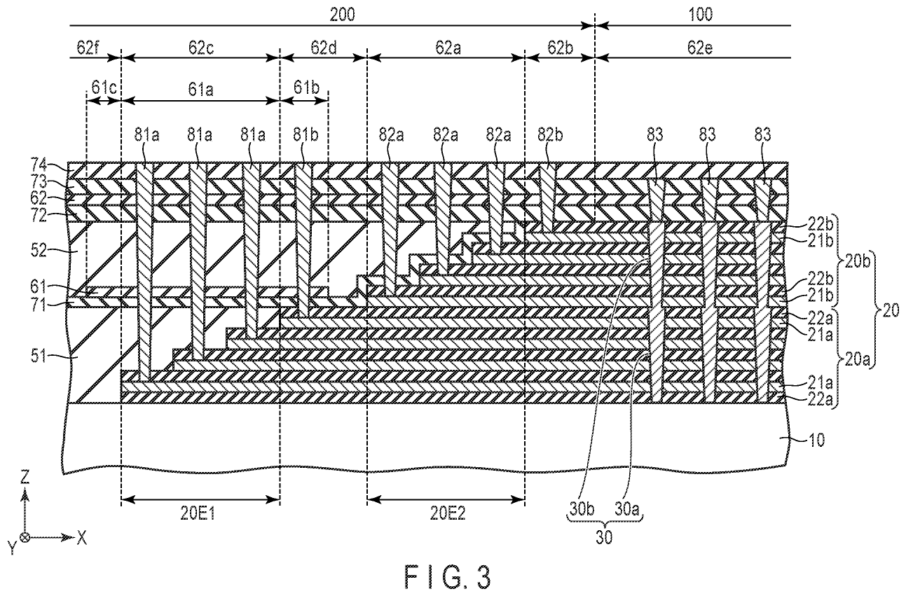

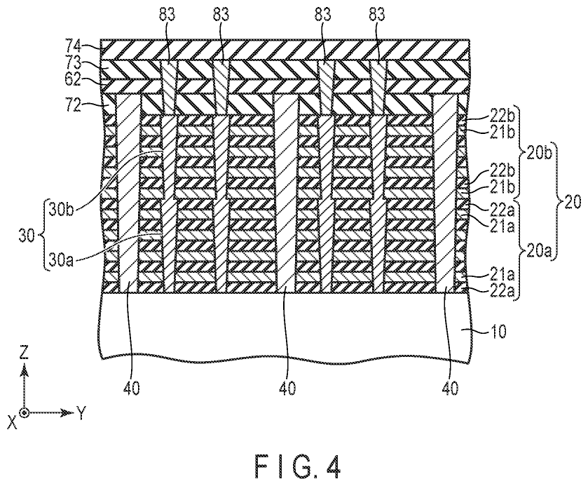

FIG. 2 is a plan pattern diagram schematically illustrating the structure of the memory region 100 and the stairs region 200. FIG. 3 is a schematic cross-sectional view of the structure of the memory region 100 and the stairs region 200. A cross-section taken along line A-A of FIG. 2 corresponds to FIG. 3. FIG. 4 is a schematic cross-sectional view of the structure of the memory region 100. A cross-section taken along line B-B of FIG. 2 corresponds to FIG. 4.

As shown in FIGS. 2, 3, and 4, the memory region 100 and the stairs region 200 include, on a semiconductor substrate 10, a stacked body 20, a plurality of pillar structures 30, a plurality of partition structures 40, interlayer insulating layers 51 and 52, stopper insulating layers 61 and 62, insulating layers 71, 72, 73, and 74, and contacts 81a, 81b, 82a, 82b, and 83.

The stacked body 20 includes a stacked portion 20a, and a stacked portion 20b provided on the upper layer side of the stacked portion 20a.

The stacked portion 20a includes a plurality of conductive layers 21a stacked to be apart from each other in the direction Z. Specifically, the stacked portion 20a has a structure in which conductive layers 21a and insulating layers 22a are stacked alternately in the direction Z.

The stacked portion 20b includes a plurality of conductive layers 21b stacked to be apart from each other in the direction Z. Specifically, the stacked portion 20b has a structure in which conductive layers 21b and insulating layers 22b are stacked alternately in the direction Z.

Note that, hereinafter, the conductive layers 21a and the conductive layers 21b may be referred to as conductive layers 21, and the insulating layers 22a and the insulating layers 22b may be referred to as insulating layers 22.

Each conductive layer 21 functions as a word line or a select gate line for a NAND string, and each insulating layer 22 has a function to insulate adjacent conductive layers 21. The conductive layer 21 is formed of a metal material such as tungsten, and the insulating layer 22 is formed of an insulative material such as silicon oxide. One or more conductive layers 21a including the lowermost conductive layer 21a function as a lower select gate line, and one or more conductive layers 21b including the uppermost conductive layer 21b function as an upper select gate line. Furthermore, a plurality of conductive layers 21 provided between one or more conductive layers 21a including the lowermost conductive layer 21a and one or more conductive layers 21b including the uppermost conductive layer 21b function as word lines.

The stacked portion 20a has an end portion 20E1 stepwise processed along the direction X, and the stacked portion 20b has an end portion 20E2 arranged beside the end portion 20E1 in the direction X and stepwise processed along the direction X. The end portions 20E1 and 20E2 are each defined by a plurality of steps. Each step is defined by a rising portion which is substantially parallel to the direction Z and a terrace portion (terrace surface) extending substantially parallel to an XY plane (plane perpendicular to the direction Z) from the upper end of the rising portion. The end portion 20E1 is defined by a plurality of rising portions of the stacked portion 20a and a plurality of terrace portions of the stacked portion 20a (excluding the uppermost terrace portion of the stacked portion 20a). The end portion 20E2 is defined by a plurality of rising portions of the stacked portion 20b and a plurality of terrace portions of the stacked portion 20b (excluding the uppermost terrace portion of the stacked portion 20b).

Note that, in FIGS. 3 and 4, for easier understanding of the structure, both the stacked portions 20a and 20b include four conductive layers 21; however, the stacked portions 20a and 20b generally include more conductive layers 21.

Each of the pillar structures 30 extends in the stacked body 20 along the direction Z and includes a semiconductor layer extending along the direction Z. Each pillar structure 30 includes a pillar portion 30a extending in the stacked portion 20a along the direction Z and a pillar portion 30b extending in the stacked portion 20b along the direction Z.

Each pillar structure 30 is surrounded by a plurality of conductive layers 21 and a plurality of insulating layers 22, and a NAND string is formed with the pillar structure 30 and the conductive layers 21 surrounding the pillar structure 30. Specifically, a memory cell is formed with the conductive layer 21 functioning as a word line and a portion of the pillar structure 30 surrounded by the conductive layer 21 functioning as the word line. Furthermore, a select transistor is formed with the conductive layer 21 functioning as the select gate line and a portion of the pillar structure 30 surrounded by the conductive layer 21 functioning as the select gate line.

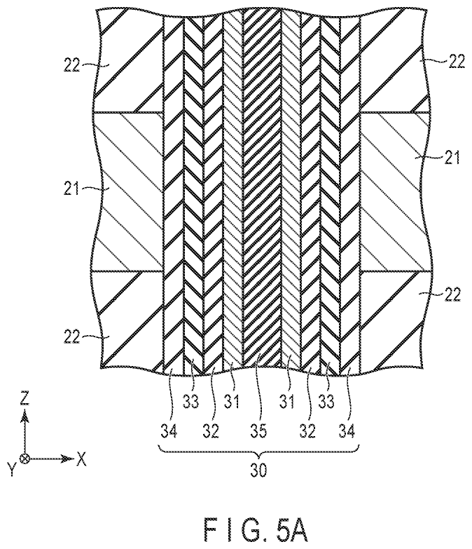

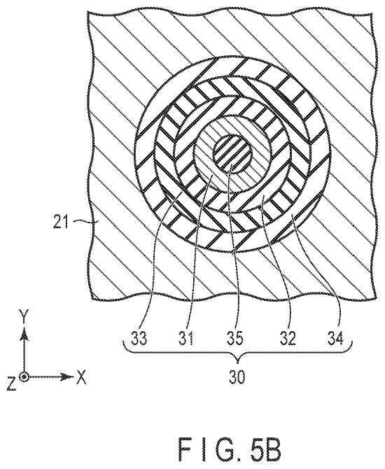

FIGS. 5A and 5B are schematic cross-sectional views of the detailed structure of a memory cell portion structured with the conductive layer 21 and the pillar structure 30. FIG. 5A is a cross-sectional view parallel to the direction Z, and FIG. 5B is a cross-sectional view perpendicular to the direction Z.

A pillar structure 30 includes a semiconductor layer 31, tunnel insulating layer 32, charge storage layer 33, block insulating layer 34, and core insulating layer 35. Both pillar portions 30a and 30b have the structure shown in FIGS. 5A and 5B. The semiconductor layer 31, tunnel insulating layer 32, charge storage layer 33, and block insulating layer 34 each have a cylindrical shape, and the core insulating layer 35 has a columnar shape. Specifically, the semiconductor layer 31 surrounds a side surface of the core insulating layer 35, the tunnel insulating layer 32 surrounds a side surface of the semiconductor layer 31, the charge storage layer 33 surrounds a side surface of the tunnel insulating layer 32, and the block insulating layer 34 surrounds a side surface of the charge storage layer 33. For example, the semiconductor layer 31 is formed of silicon, the tunnel insulating layer 32 is formed of silicon oxide, the charge storage layer 33 is formed of silicon nitride, the block insulating layer 34 is formed of silicon oxide, and the core insulating layer 35 is formed of silicon oxide.

Each of the partition structures 40 extends in the directions X and Z in the stacked body 20, and the stacked body 20 is partitioned into a plurality of portions in the direction Y by the partition structures 40. Each portion of the stacked body 20 partitioned by the partition structures 40 forms one block which is a data erase unit, for example. A level of the upper surface of each of the partition structures 40 in the height direction is substantially the same as a level of the lower surface of each stopper insulating layer 62 in the height direction, which will be described later.

The interlayer insulating layer 51 covers an end portion 20E1 of the stacked portion 20a. Further, the interlayer insulating layer 52 is provided on the upper layer side of the interlayer insulating layer 51 and covers an end portion 20E2 of the stacked portion 20b. The interlayer insulating layers 51 and 52 are formed of silicon oxide containing silicon and oxygen.

The stopper insulating layer 61 includes stopper portions 61a, 61b, and 61c provided continuously, and is not provided between the stacked portion 20a and the stacked portion 20b. The stopper insulating layer 61 is formed of a material with a main component which is different from that of a material of the interlayer insulating layer 51 and that of a material of the interlayer insulating layer 52. Specifically, the stopper insulating layer 61 is formed of silicon nitride containing silicon and nitrogen.

The stopper portion 61a is provided between the interlayer insulating layer 51 and the interlayer insulating layer 52 and above the end portion 20E1 of the stacked portion 20a (specifically, vertically above the entirety of the end portion 20E1 in the direction X except a portion at which the contact 81a penetrates), and the entirety of the stopper portion 61a extends flat along the X-Y plane (plane perpendicular to the direction Z). That is, the stopper portion 61a crosses a plurality of steps of the end portion 20E1, and the entirety of the stopper portion 61a is provided flat along the upper surface of the flattened interlayer insulating layer 51 without a step.

The stopper portion 61b is provided, between the end portion 20E1 and the end portion 20E2 arranged beside each other in the X direction, from the stopper portion 61a continuously so as to be opposed to the uppermost surface of the stacked portion 20a in the direction Z. As seen from the direction Z, a boundary between the stopper portion 61a and the stopper portion 61b corresponds to the position of the uppermost rising portion of the end portion 20E1.

The stopper portion 61c is provided between the interlayer insulating layer 51 and the interlayer insulating layer 52 and is provided continuously from the stopper portion 61a. As seen from the direction Z, the stopper portion 61c is provided outside the end portion 20E1, and a boundary between the stopper portion 61a and the stopper portion 61c corresponds to the position of the lowermost rising portion of the end portion 20E1.

In the present embodiment, the entirety of the stopper insulating layer 61 has a flat shape along the X-Y plane without a step. Further, as seen from the direction Z, the stopper insulating layer 61 is provided between partition structures 40 adjacent to each other so as to be apart from the partition structures 40 adjacent to each other.

The stopper insulating layer 62 includes stopper portions 62a, 62b, 62c, 62d, 62e, and 62f continuously provided. The stopper portions 62a, 62b, 62c, 62d, and 62f are provided in the stairs region 200, and the stopper portion 62e is provided in the memory region 100. The stopper insulating layer 62 is formed of a material with a main component which is different from that of a material of the interlayer insulating layer 51 and that of a material of the interlayer insulating layer 52. Specifically, the stopper insulating layer 62 is formed of the same material of the stopper insulating layer 61, that is, silicon nitride containing silicon and nitrogen.

The stopper portion 62a is provided on the upper layer side of the interlayer insulating layer 52 and above the end portion 20E2 of the stacked portion 20b (specifically, vertically above the entirety of the end portion 20E2 except a portion at which the contact 82a penetrates). The entirety of the stopper portion 62a has a flat shape without a step, and crosses a plurality of steps of the end portion 20E2.

The stopper portion 62b is provided continuously from the stopper portion 62a so as to be opposed to the uppermost surface of the stacked portion 20b in the direction Z.

The stopper portion 62c is provided on the upper layer side of the interlayer insulating layer 52 and above the end portion 20E1 of the stacked portion 20a (specifically, vertically above the entirety of the end portion 20E1 except a portion at which the contact 81a penetrates).

The stopper portion 62d is provided on the upper layer side of the interlayer insulating layer 52 and between the stopper portion 62a and the stopper portion 62c.

The stopper portion 62e is provided continuously from the stopper portion 62b so as to be opposed to the uppermost surface of the stacked portion 20b in the direction Z.

The stopper portion 62f is provided continuously from the stopper portion 62c on the upper layer side of the interlayer insulating layer 52, and is provided outside the end portion 20E1 as seen from the direction Z.

As seen from the direction Z, the boundary between the stopper portion 62a and the stopper portion 62b corresponds to a position of the uppermost rising portion of the end portion 20E2 of the stacked portion 20b. As seen from the direction Z, the boundary between the stopper portion 62a and the stopper portion 62d corresponds to a position of the lowermost rising portion of the end portion 20E2. As seen from the direction Z, the boundary between the stopper portion 62c and the stopper portion 62d corresponds to a position of the uppermost rising portion of the end portion 20E1 of the stacked portion 20a. As seen from the direction Z, the boundary between the stopper portion 62c and the stopper portion 62f corresponds to a position of the lowermost rising portion of the end portion 20E1. As seen from the direction Z, the boundary between the stopper portion 62b and the stopper portion 62e corresponds to the boundary between the memory region 100 and the stairs region 200.

In the present embodiment, the entirety of the stopper insulating layer 62 has a flat shape along the X-Y plane without a step. Further, as seen from the direction Z, the entirety of the pattern of the stopper insulating layer 61 is located inside the pattern of the stopper insulating layer 62.

The insulating layer 71 includes a portion provided on the interlayer insulating layer 51, portion provided on the uppermost terrace portion of the stacked portion 20a, and portion provided on the end portion 20E2 of the stacked portion 20b, and is formed of silicon oxide. The stopper insulating layer 61 is provided on the insulating layer 71. Thus, the stopper insulating layer 61 is provided between the interlayer insulating layer 52 and the insulating layer 71.

The insulating layer 72 includes a portion provided on the interlayer insulating layer 52 and a portion provided on the uppermost surface of the stacked portion 20b. The stopper insulating layer 62 is provided on the insulating layer 72, and the insulating layer 73 is provided on the stopper insulating layer 62. Thus, the stopper insulating layer 62 is provided between the insulating layers 72 and 73. The insulating layer 74 is provided on the insulating layer 73. The insulating layers 72, 73, and 74 are formed of silicon oxide.

Contacts 81a, 81b, 82a, and 82b are connected to corresponding conductive layers 21 of the stacked body 20, and control signals are supplied to corresponding conductive layers 21 from the contacts 81a, 81b, 82a, and 82b.

A plurality of contacts 81a are connected to a plurality of conductive layers 21a of the stacked portion 20a, respectively, except the uppermost conductive layer 21a. Specifically, the plurality of contacts 81a penetrate the insulating layer 74, insulating layer 73, stopper portion 62c of the stopper insulating layer 62, insulating layer 72, interlayer insulating layer 52, stopper portion 61a of the stopper insulating layer 61, insulating layer 71, interlayer insulating layer 51, and different insulating layers 22a of a plurality of insulating layers 22a, and are connected to different conductive layers 21a of the plurality of conductive layers 21a.

A contact 81b is connected to the uppermost conductive layer 21a of a plurality of conductive layers 21a of the stacked portion 20a. Specifically, the contact 81b penetrates the insulating layer 74, insulating layer 73, stopper portion 62d of the stopper insulating layer 62, insulating layer 72, interlayer insulating layer 52, stopper portion 61b of the stopper insulating layer 61, insulating layer 71, and uppermost insulating layer 22a of the stacked portion 20a, and connected to the uppermost conductive layer 21a of the stacked portion 20a. That is, the contact 81b, different from the contact 81a, does not penetrate the interlayer insulating layer 51.

A plurality of contacts 82a are connected to a plurality of conductive layers 21b of the stacked portion 20b, respectively, except the uppermost conductive layer 21b. Specifically, the plurality of contacts 82a penetrate the insulating layer 74, insulating layer 73, stopper portion 62a of the stopper insulating layer 62, insulating layer 72, interlayer insulating layer 52, insulating layer 71 and different insulating layers 22b of a plurality of insulating layers 22b and are connected to different conductive layers 21b of the plurality of conductive layers 21b. Thus, the plurality the contacts 82a do not penetrate the stopper insulating layer 61.

A contact 82b is connected to the uppermost conductive layer 21b of a plurality of conductive layers 21b of the stacked portion 20b. Specifically, the contact 82b penetrates the insulating layer 74, insulating layer 73, stopper portion 62b of the stopper insulating layer 62, insulating layer 72 and the uppermost insulating layer 22b of the stacked portion 20b and is connected to the uppermost conductive layer 21b of the stacked portion 20b. That is, the contact 82b, different from the contact 82a, does not penetrate the interlayer insulating layer 52.

Levels of the upper ends of the aforementioned contacts 81a, 81b, 82a, and 82b in the height direction are substantially identical with one another. That is, levels of the upper ends of the contacts 81a, 81b, 82a, and 82b in the height direction are substantially the same as a level of the upper surface of the insulating layer 74.

A plurality of contacts 83 are connected to semiconductor layers 31 in a plurality of pillar structures 30, respectively, and signals are transmitted/received between the pillar structure 30 and the bit line (which is not shown) (between the NAND string and the bit line) through the contact 83.

The plurality of contacts 83 penetrate the insulating layer 73, stopper portion 62e of the stopper insulating layer 62 and insulating layer 72 and are connected to the semiconductor layers 31 of different pillar structures 30 of a plurality of pillar structures 30, respectively. In the present embodiment, the contacts 83 do not penetrate the insulating layer 74. Thus, levels of the upper ends of the contacts 83 in the height direction are lower than levels of the upper ends of the contacts 81a, 81b, 82a, and 82b in the height direction.

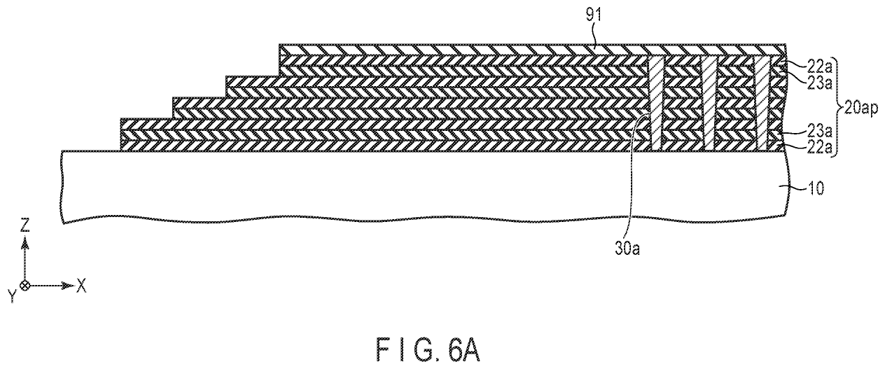

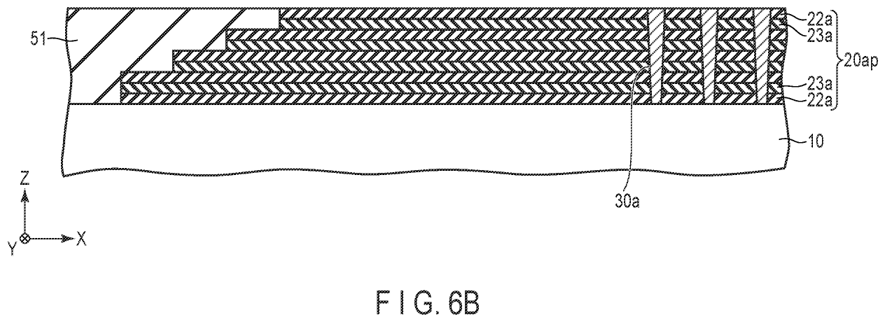

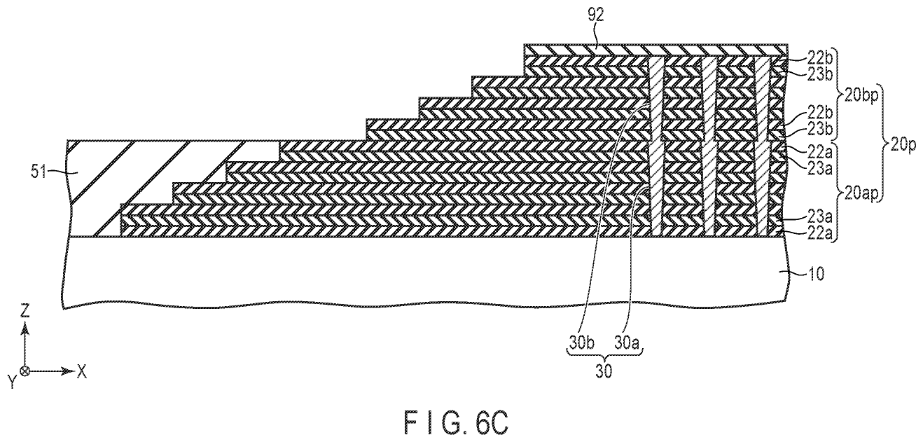

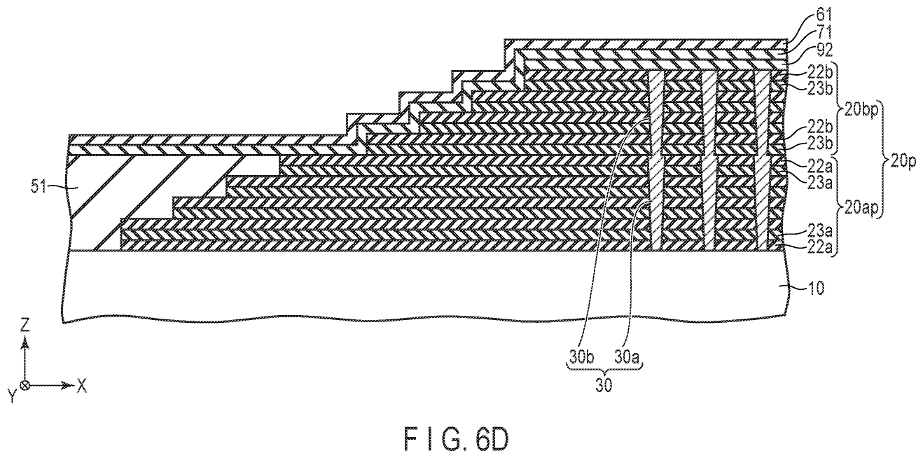

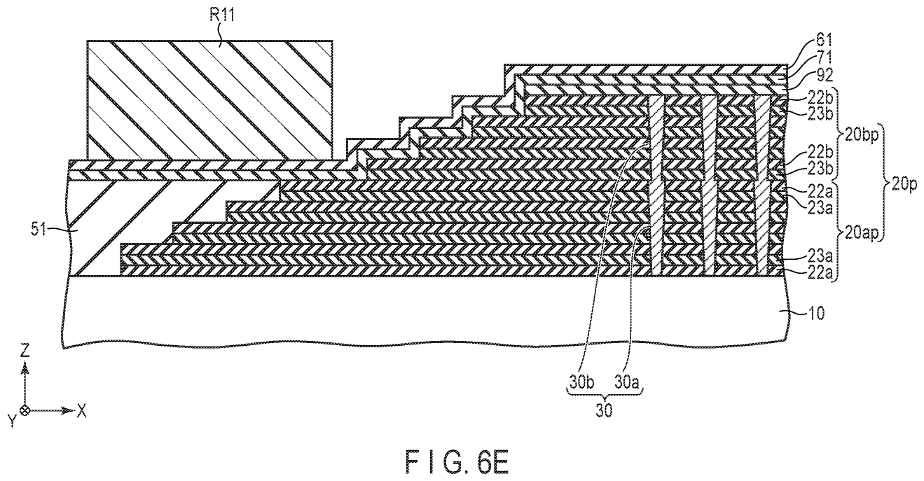

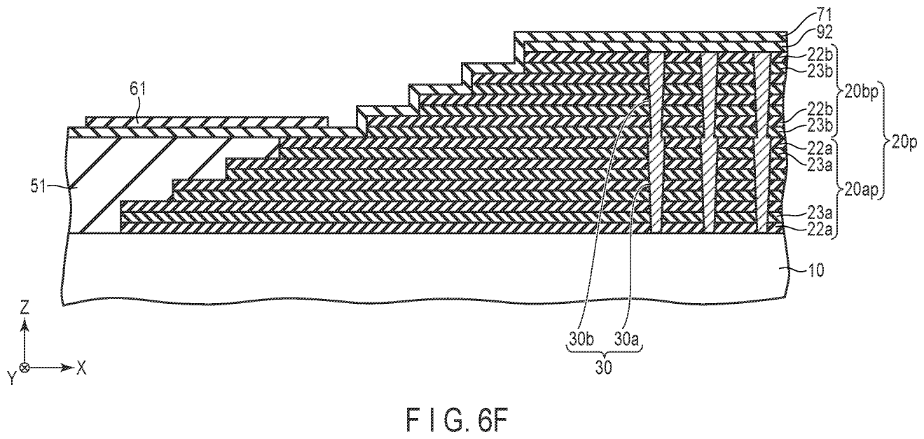

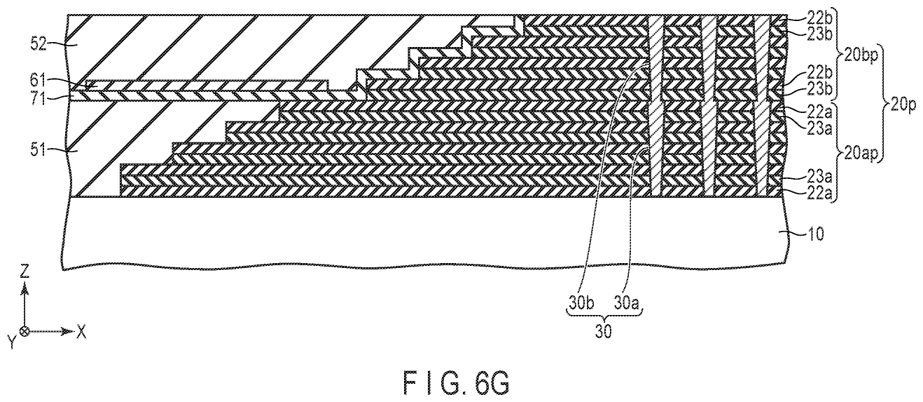

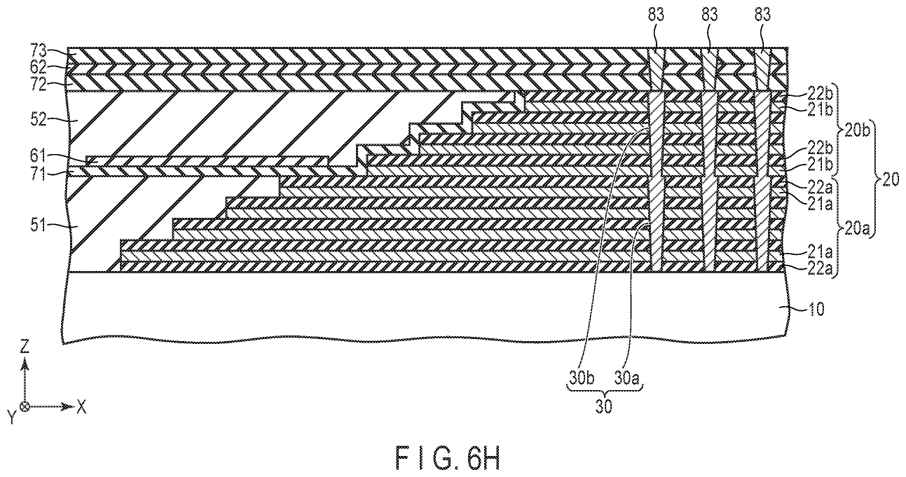

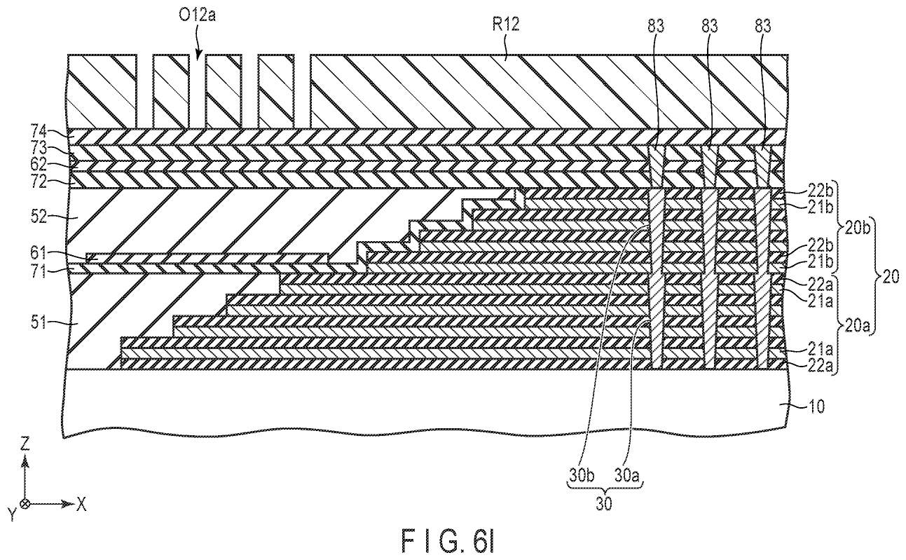

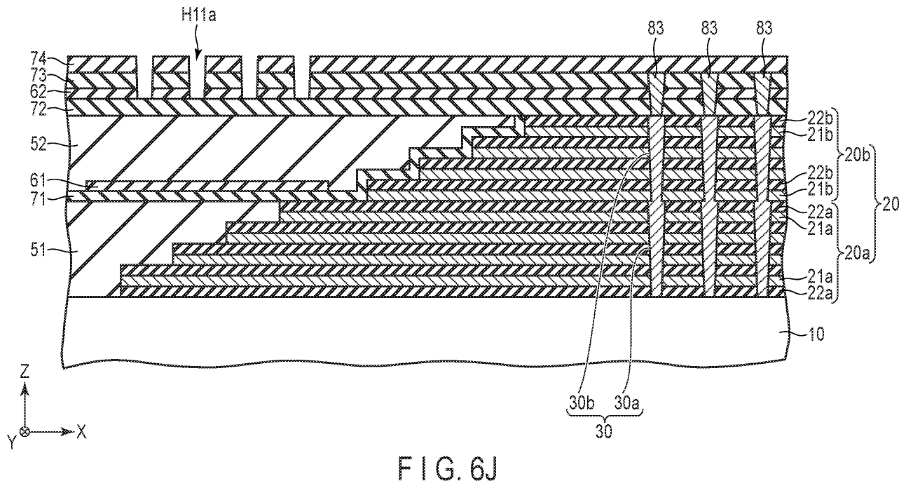

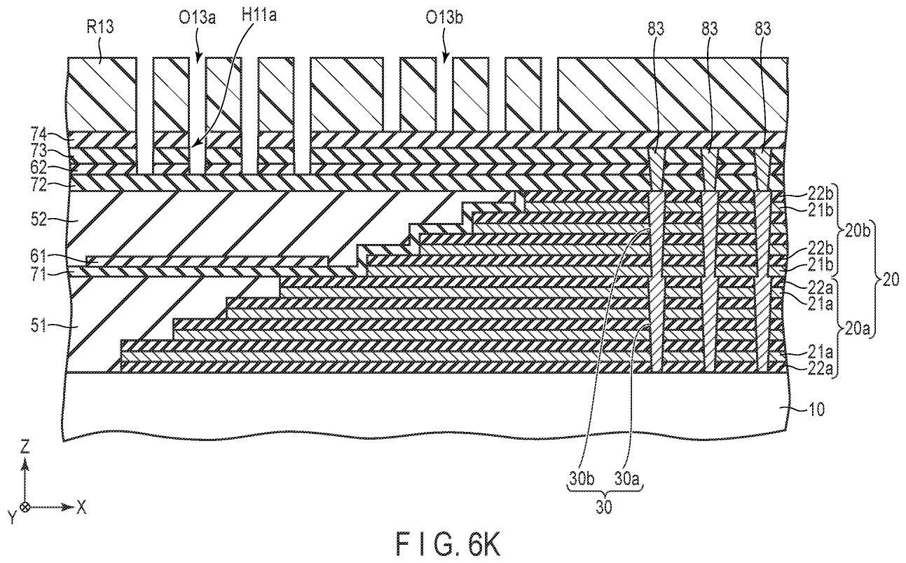

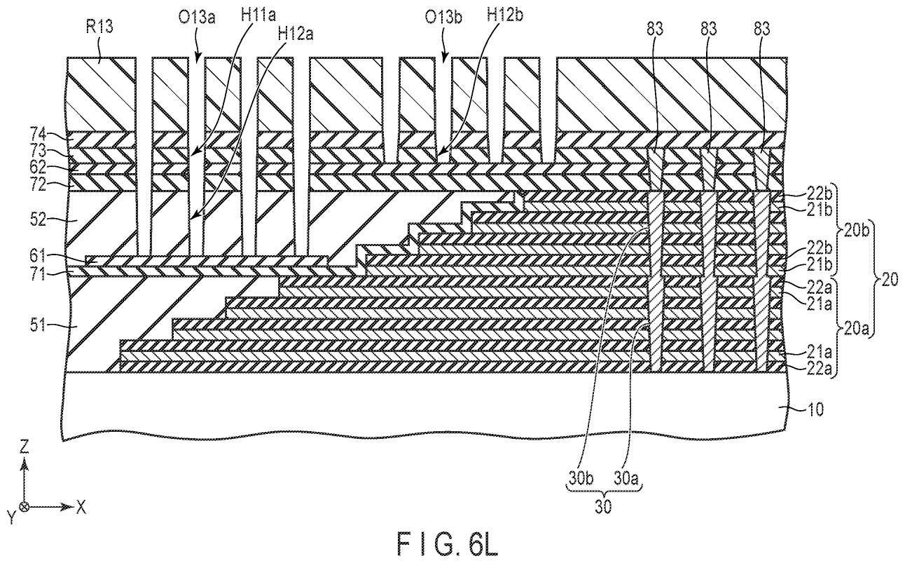

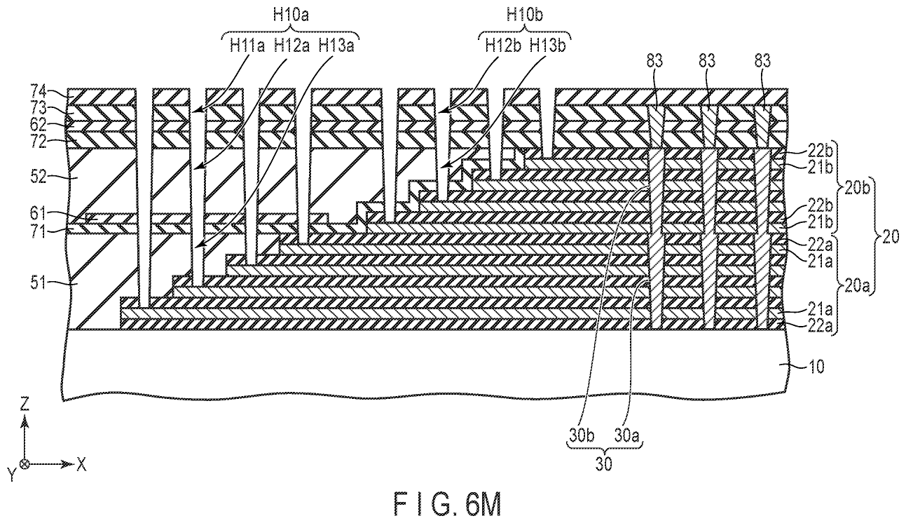

Now, a manufacturing method of the semiconductor memory device of the present embodiment will be explained with reference to cross-sectional views of FIGS. 6A to 6M and FIG. 3.

Initially, as shown in FIG. 6A, a preliminary stacked portion 20ap is formed on the semiconductor substrate 10. The preliminary stacked portion 20ap has a structure in which insulating layers 22a and sacrificial layers 23a are stacked alternately in the direction Z. The insulating layer 22a is formed of silicon oxide, and the sacrificial layer 23a is formed of silicon nitride. Then, a plurality of holes are formed in the preliminary stacked portion 20ap, and pillar portions 30a are formed in the holes. Note that, a similar process may be performed on the end portion of the preliminary stacked portion 20ap in the direction X to form a plurality of support pillar portions (which are not shown) supporting the structure with a plurality of spaces in the stairs region 200 when a replacement process which will be described later is performed. Furthermore, a silicon nitride layer is formed as an insulating layer 91 on the preliminary stacked portion 20ap. Further, the end portion of the preliminary stacked portion 20ap in the direction X is stepwise processed.

Then, as shown in FIG. 6B, a silicon oxide layer is formed on the structure obtained in the process of FIG. 6A. Then, the silicon oxide layer is flattened using the insulating layer 91 as a stopper, and the insulating layer 91 is removed. Thus, an interlayer insulating layer 51 formed of silicon oxide can be obtained.

Then, as shown in FIG. 6C, a preliminary stacked portion 20bp is formed on the structure obtained in the process of FIG. 6B. The preliminary stacked portion 20bp has a structure in which insulating layers 22b and sacrificial layers 23b are stacked alternately in the direction Z. The insulating layer 22b is formed of silicon oxide, and the sacrificial layer 23b is formed of silicon nitride. Then, a plurality of holes are formed in the preliminary stacked portion 20bp, and pillar portions 30b are formed in the holes. Thus, a pillar structure 30 with pillar portions 30a and 30b can be obtained. As mentioned above, a similar process may be performed on the end portion of the preliminary stacked portion 20bp in the direction X to form a plurality of support pillar portions (which are not shown) supporting the structure with a plurality of spaces in the stairs region 200 when a replacement process which will be described later is performed. Furthermore, a silicon nitride layer as an insulating layer 92 is formed on the preliminary stacked portion 20bp. Further, the end portion in the direction X of the preliminary stacked portion 20bp is stepwise processed. Through the above processes, a preliminary stacked body 20p including the preliminary stacked portion 20ap and the preliminary stacked portion 20bp formed on the preliminary stacked portion 20ap is obtained.

Then, as shown in FIG. 6D, a silicon oxide layer is formed as an insulating layer 71 on the structure obtained in the process of FIG. 6C, and a silicon nitride layer as a stopper insulating layer 61 is formed on the insulating layer 71.

Then, as shown in FIG. 6E, a resist pattern R11 is formed on the stopper insulating layer 61.

Then, as shown in FIG. 6F, the stopper insulating layer 61 is etched using the resist pattern R11 as a mask to form a pattern of the stopper insulating layer 61.

Then, as shown in FIG. 6G, a silicon oxide layer is formed on the structure obtained in the process of FIG. 6F. Then, the silicon oxide layer and the insulating layer 71 are etched using the insulating layer 92 as a stopper for flattening, and the insulating layer 92 is removed. As a result, an interlayer insulating layer 52 formed of silicon oxide is obtained.

Then, as shown in FIG. 6H, a silicon oxide layer is formed as an insulating layer 72 on the structure obtained in the process of FIG. 6G. Then, a plurality of trenches for partition structures 40 as shown in FIGS. 2 and 4 are formed in the insulating layer 72 and the preliminary stacked body 20p. Then, a replacement process for the sacrificial layers 23a and 23b is performed. Specifically, the sacrificial layers 23a and 23b are etched through the trenches for the partition structures 40 to form a plurality of spaces, and then, the spaces are filled with a metal material such as tungsten to form a plurality of conductive layers 21a and 21b. As a result, a stacked body 20 including the stacked portion 20a and the stacked portion 20b is obtained. In the replacement process, the stopper insulating layer 61 is apart from the trenches for the partition structure 40, and thus, the stopper insulating layer 61 remains without being etched. Then, a plurality of partition structures 40 are formed by filling the trenches for the partition structures 40 with a predetermined material.

Then, a silicon nitride layer as a stopper insulating layer 62 is formed on the structure where the insulating layer 72 and the partition structure 40 are formed. Furthermore, a silicon oxide layer as an insulating layer 73 is formed on the stopper insulating layer 62. Then, a plurality of contact holes are formed in the insulating layer 72, stopper insulating layer 62, and insulating layer 73, and the contact holes are filled with a conductive material to form contacts 83. Specifically, the insulating layer 73 is etched using the stopper insulating layer 62 as a stopper, and then the stopper insulating layer 62 is etched using a different etching gas. Furthermore, a layer on the lower layer side of the stopper insulating layer 62 is etched to reach the contact holes to corresponding pillar structure 30, and then, the contacts 83 are formed in the contact holes.

Then, as shown in FIG. 6I, a silicon oxide layer is formed as an insulating layer 74 on the structure obtained in the process of FIG. 6H. Furthermore, a resist pattern R12 with a plurality of openings O12a is formed to correspond to a region where contacts 81a and 81b are to be formed, on the insulating layer 74.

Then, as shown in FIG. 6J, the insulating layer 74, insulating layer 73, and stopper insulating layer 62 are etched using the resist pattern R12 formed in the process of FIG. 6I as a mask. Specifically, the insulating layer 74 and the insulating layer 73 are etched using the stopper insulating layer 62 as a stopper, and then, the stopper insulating layer 62 is etched using a different etching gas. As a result, a plurality of holes H11a are formed.

Then, as shown in FIG. 6K, a resist pattern R13 with a plurality of openings O13a and a plurality of openings O13b is formed to correspond to a region where contacts 81a, 81b, 82a, and 82b are to be formed, on the structure obtained in the process of FIG. 6J. As seen from the direction Z, the openings O13a are positioned to correspond to the holes H11a.

Then, as shown in FIG. 6L, etching is performed using the resist pattern R13 formed in the process of FIG. 6K as a mask. Specifically, under the openings O13a and the holes H11a, the insulating layer 72 and the interlayer insulating layer 52 are etched using the stopper insulating layer 61 as an etching stopper to form a plurality holes H12a. Under the openings O13b, the insulating layer 74 and the insulating layer 73 are etched using the stopper insulating layer 62 as an etching stopper to form a plurality of holes H12b. The holes H12a and H12b are formed in the common etching process.

Then, as shown in FIG. 6M, etching is performed using the resist pattern R13 and the pattern obtained in the process of FIG. 6L as masks. Specifically, under the openings O13a, holes H11a and holes H12a, the stopper insulating layer 61, insulating layer 71, interlayer insulating layer 51, and insulating layer 22a are etched to form a plurality of holes H13a. Under the openings O13b and the holes H12b, the stopper insulating layer 62, insulating layer 72, interlayer insulating layer 52, insulating layer 71, and insulating layer 22b are etched to form a plurality of holes H13b. Specifically, the stopper insulating layers 61 and 62 are etched in the common process, and then, layers on the lower layer side of the stopper insulating layers 61 and layers on the lower layer side of the stopper insulating layers 62 are etched in the common process.

Through the above processes, contact holes H10a including holes H11a, H12a, and H13a, and contact holes H10b including holes H12b, and H13b are obtained.

Then, as shown in FIG. 3, the contact holes H10a and H10b are filled with a conductive material, and thus, the contacts 81a, 81b, 82a, and 82b are formed in the common process.

As above, in the present embodiment, the stopper insulating layer 61 including the stopper portion 61a is provided. Thus, contacts can be properly formed as described below.

As shown in FIG. 3, heights of the contacts 81a, 81b, 82a, and 82b are different. Thus, depths of the contact holes are different. The depth of the contact hole H10a is relatively deeper, and the depth of the contact hole H10b is relatively shallower. Thus, if there is not a stopper insulating layer 61 while contact holes H10a and H10b are simultaneously formed, etching may be exceedingly progressed in the part in which the contact hole H10b is formed as compared with the part in which the contact hole H10a is formed. As a result, the contact hole H10b may penetrate the conductive layer 21b to reach the lower layer side of the conductive layer 21b.

In the present embodiment, with the stopper insulating layer 61 used as an etching stopper, the interlayer insulating layer 52 is etched, and then, the interlayer insulating layer 51 is etched, thereby forming the contact holes H10a. Thus, when performing the etching of the interlayer insulating layer 51 to form the contact holes H10a, by performing etching of the interlayer insulating layer 52 to form the contact holes H10b, such exceeding progress of etching in the part in which the contact holes H10b are formed can be suppressed. Thus, in the present embodiment, the contact holes H10a and H10b can be properly formed, and the contacts 81a, 81b, 82a, and 82b can be properly formed.

Furthermore, in the present embodiment, the stacked body 20 includes stacked portions 20a and 20b. When forming a stacked body 20 including stacked portions 20a and 20b, before forming a stacked portion 20b, a flattened interlayer insulating layer 51 covering the end portion 20E1 of the stacked portion 20a is formed. In the present embodiment, the stopper insulating layer 61 is formed on the flattened interlayer insulating layer 51, and thus, the flattened stopper insulating layer 61 can be formed without complicated processes.

Furthermore, in the present embodiment, the stopper insulating layer 62 is provided in addition to the stopper insulating layer 61, and thus, as shown in FIG. 6M, holes 13a and 13b can be formed in a substantially same condition. Thus, the contact holes H10a and H10b can be further precisely formed, and the contacts 81a, 81b, 82a, and 82b can be further precisely formed.

Furthermore, in the present embodiment, the stopper portion 62e of the stopper insulating layer 62 is provided to be opposed to the uppermost surface of the stacked portion 20b in the memory region 100 in the direction Z, and thus, when performing etching with respect to the layer on the upper layer side of the pillar structures 30 in the process of FIG. 6H to form contacts 83 for the pillar structures 30, the stopper portion 62e can be used as an etching stopper. Thus, even if there is an alignment shift between the pillar structures 30 and the contacts 83, a possibility of excessive etching to reach the uppermost conductive layer 21 in the portion of the contact hole which is not positioned on the pillar structure 30 as seen from the direction Z can be avoided. Thus, contacts 83 on the pillar structures 30 can be precisely formed while being apart from the uppermost conductive layer 21.

Note that, in the present embodiment, lithography process is performed twice to form the contact holes H10a. That is, the resist pattern R12 with the openings O12a is formed in the process of FIG. 6I, and the resist pattern R13 with the openings O13a is formed in the process of FIG. 6K. In that case, ideally, the position of the center of the opening O12a and the position of the center of the opening O13a match as seen from the direction Z. However, in an actual manufacturing process, generally, an alignment shift would occur by which the position of the center of the opening O12a and the position of the center of opening O13a do not match.

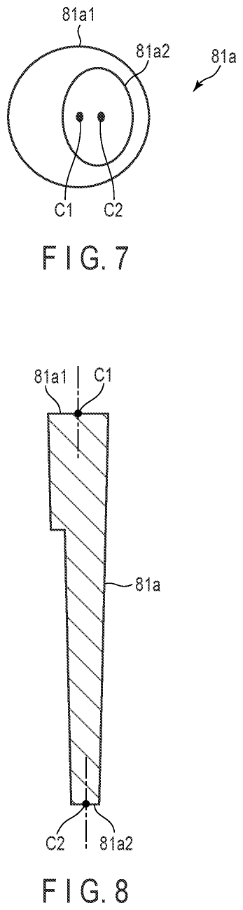

FIG. 7 and FIG. 8 each are schematic view of the pattern and shape of contact 81a when an alignment shift occurs. FIG. 7 is a schematic view of patterns of an upper end 81a1 and a lower end 81a2 of the contact 81a as seen from the direction Z. FIG. 8 is a cross-sectional view of the contact 81a, which is parallel to the direction Z. As shown in FIGS. 7 and 8, as seen from the direction Z, a center C1 of the upper end 81a1 of the contact 81a and a center C2 of the lower end 81a2 of the contact 81a are shifted from each other.

As can be understood from the above, even if an alignment shift occurs, the aforementioned advantage of the embodiment can be achieved.

Note that, the above-described manufacturing method is an example, and it can be modified by inserting another process between the aforementioned processes, omitting part of the processes, unifying some processes together, and changing the order of the processes. In such a modification, for example, the stopper portion 61a of the stopper insulating layer 61 may be partially penetrated by a support pillar portion (which is not shown) or the like supporting the structure with a plurality of spaces in the replacement process.

### Second Embodiment

Now, a second embodiment will be described. Note that, the basic elements are similar to those of the first embodiment, and the description of the elements explained in the first embodiment will be omitted.

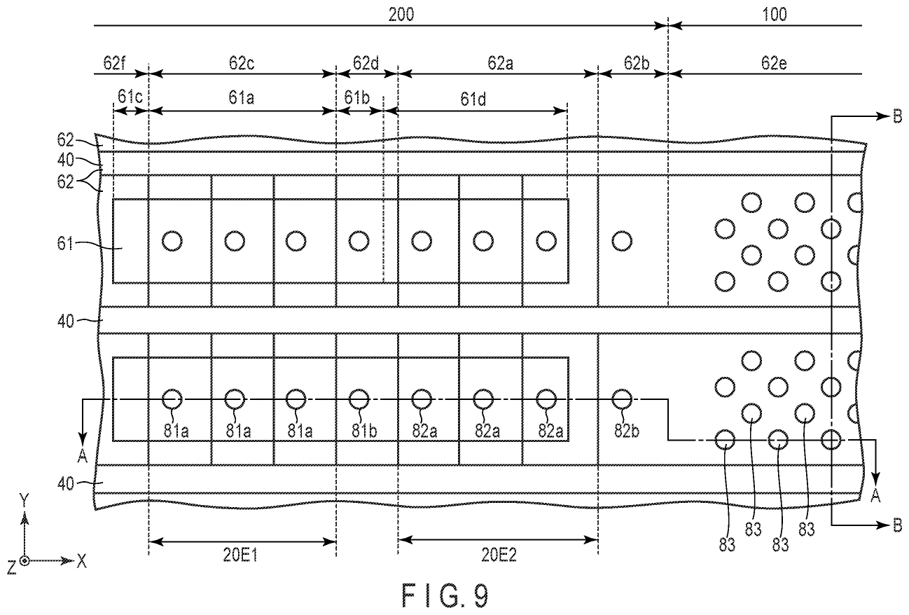

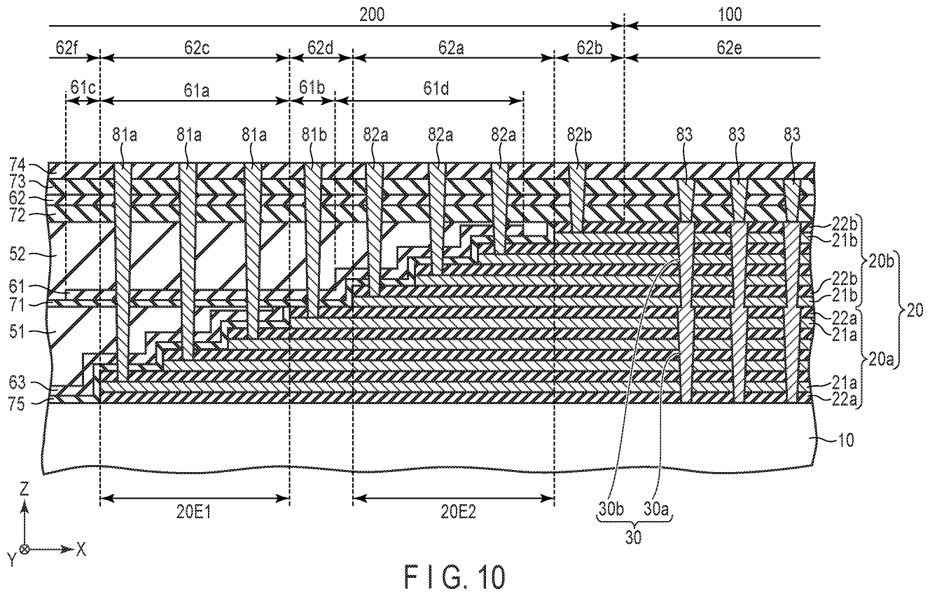

FIG. 9 is a plan pattern diagram schematically illustrating the structure of a memory region 100 and a stairs region 200 of a semiconductor memory device of the present embodiment. FIG. 10 is a schematic cross-sectional view of the structure of the memory region 100 and the stairs region 200. The cross-section taken along line A-A of FIG. 9 corresponds to FIG. 10. Note that, the cross-section taken along line B-B of FIG. 9 is similar to that of FIG. 4 of the first embodiment.

In the present embodiment, a stopper insulating layer 61 includes, in addition to stopper portions 61a, 61b, and 61c, a stopper portion 61d provided along an end portion 20E2 of a stacked portion 20b. The stopper portions 61a, 61b, 61c, and 61d are provided continuously. Thus, in the present embodiment, a plurality of contacts 82a penetrate the stopper portion 61d in addition to the structure of the first embodiment.

Furthermore, the semiconductor memory device of the present embodiment further includes a stopper insulating layer 63 provided along an end portion 20E1 of a stacked portion 20a and an insulating layer 75 provided between the end portion 20E1 and the stopper insulating layer 63. Thus, in the present embodiment, a plurality of contacts 81a penetrate the stopper insulating layer 63 and the insulating layer 75 in addition to the structure of the first embodiment.

The stopper insulating layer 63 is formed of a material with a main component which is different from that of the material of the interlayer insulating layer 51 and that of the material of the interlayer insulating layer 52. Specifically, the stopper insulating layer 63 is formed of the same material used for the stopper insulating layers 61 and 62, that is, silicon nitride containing silicon and nitrogen. The insulating layer 75 is formed of silicon oxide.

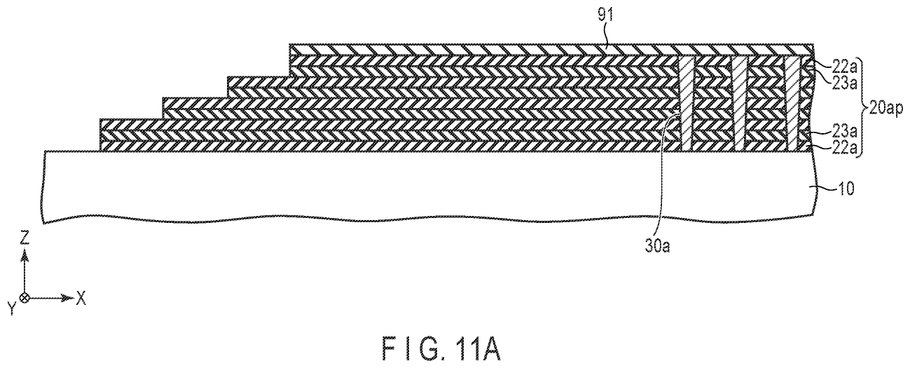

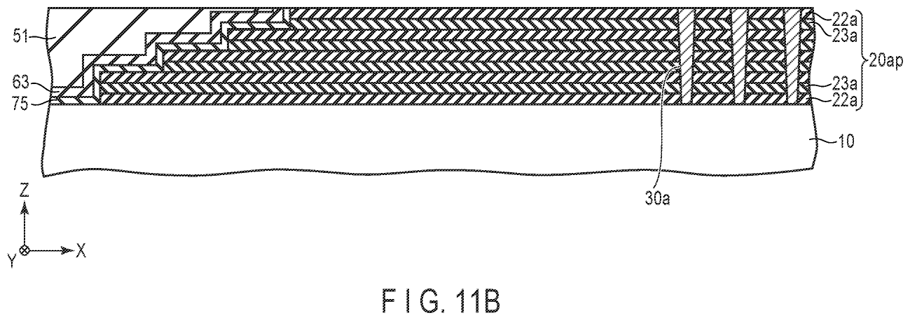

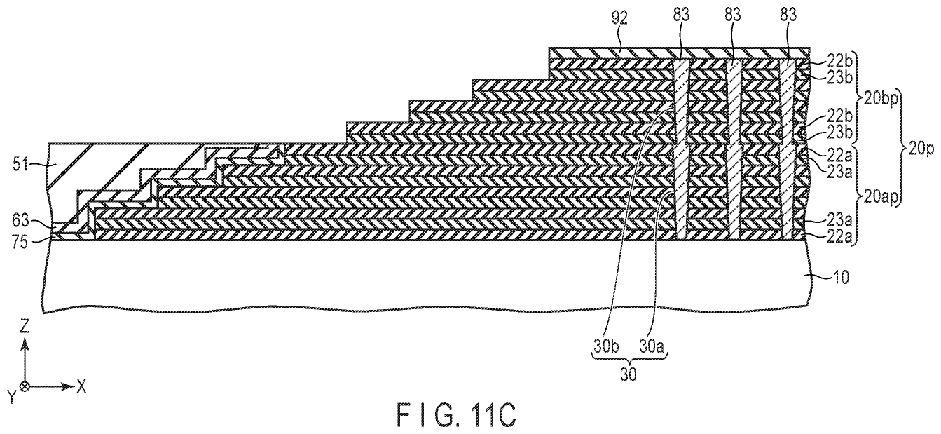

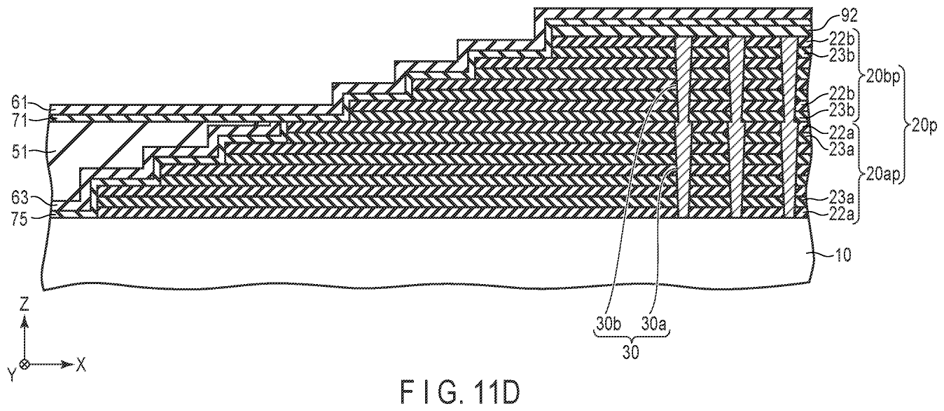

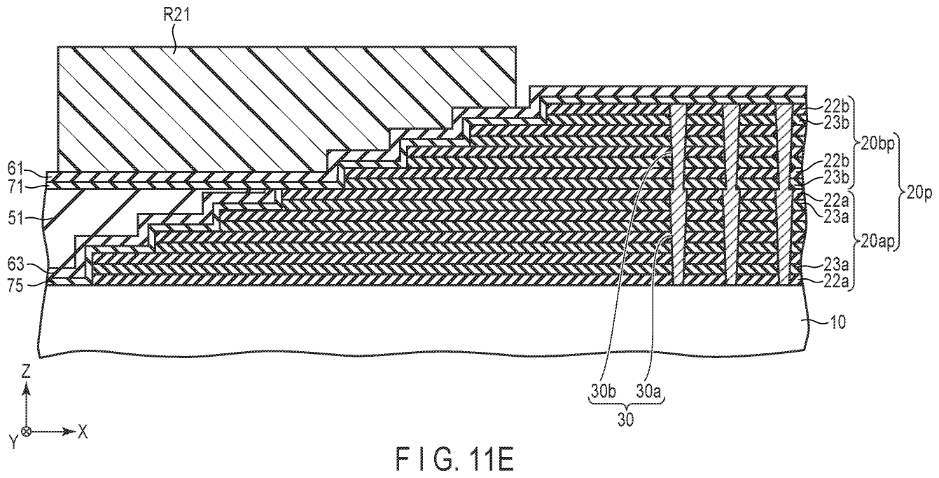

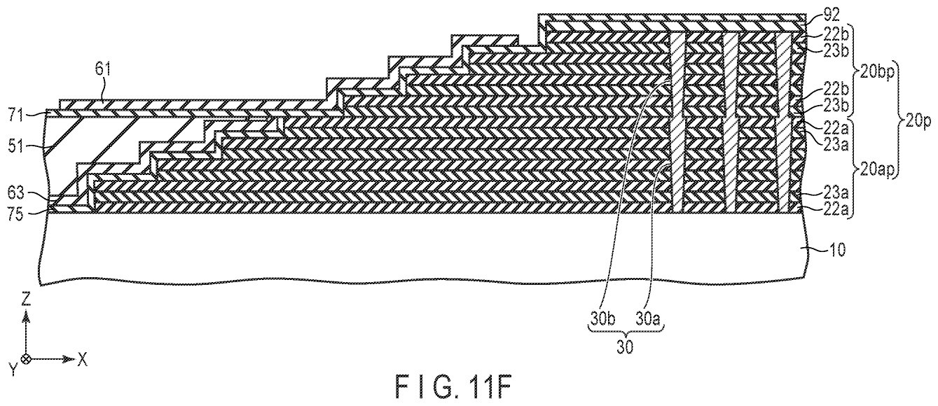

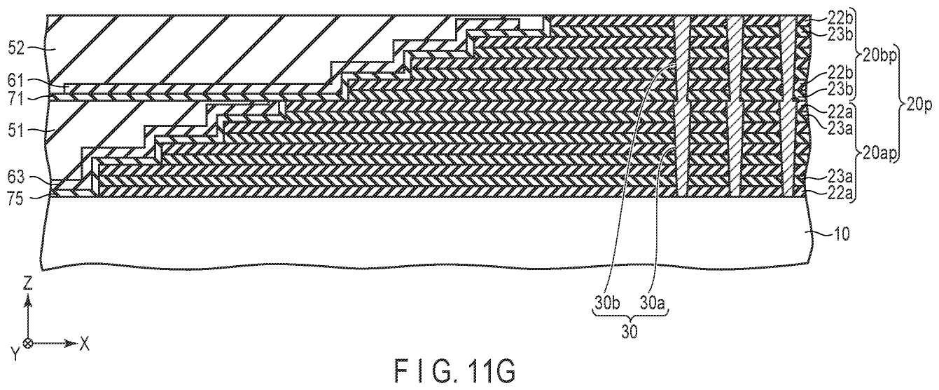

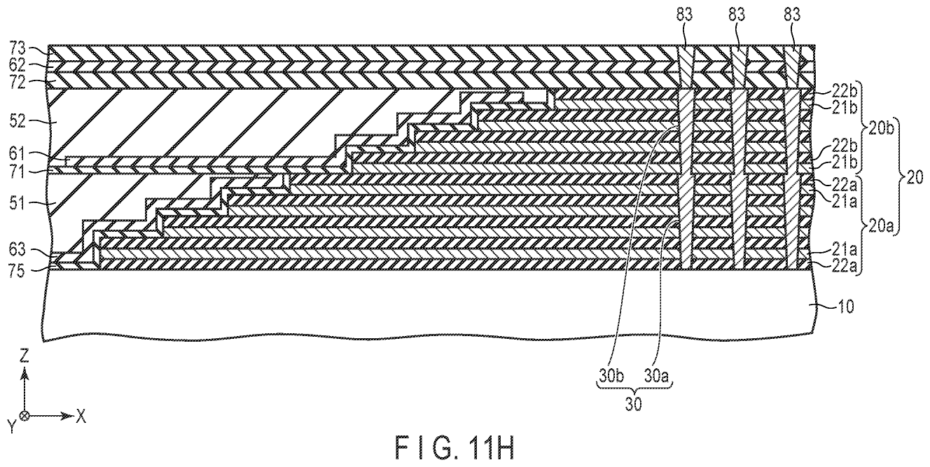

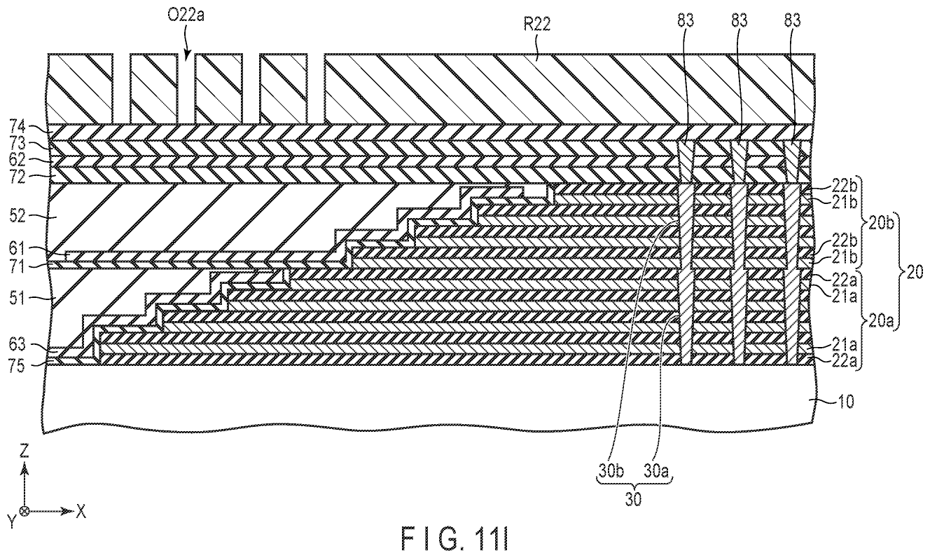

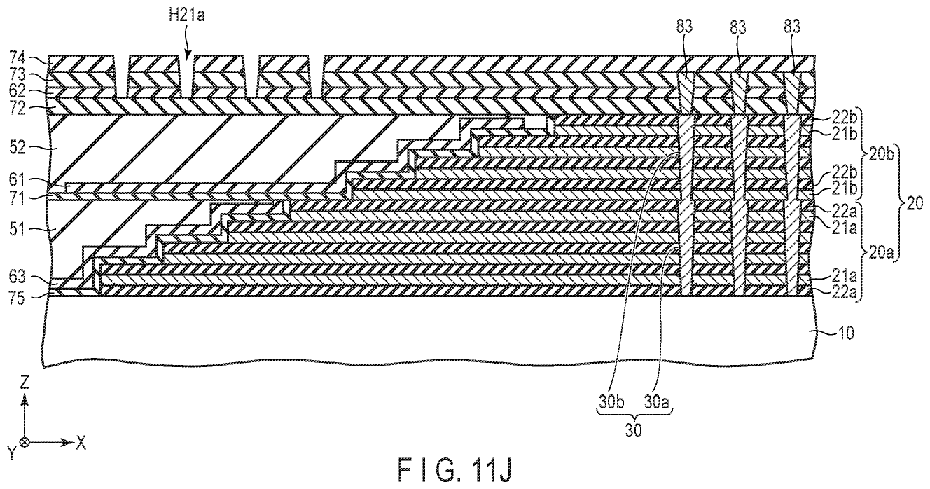

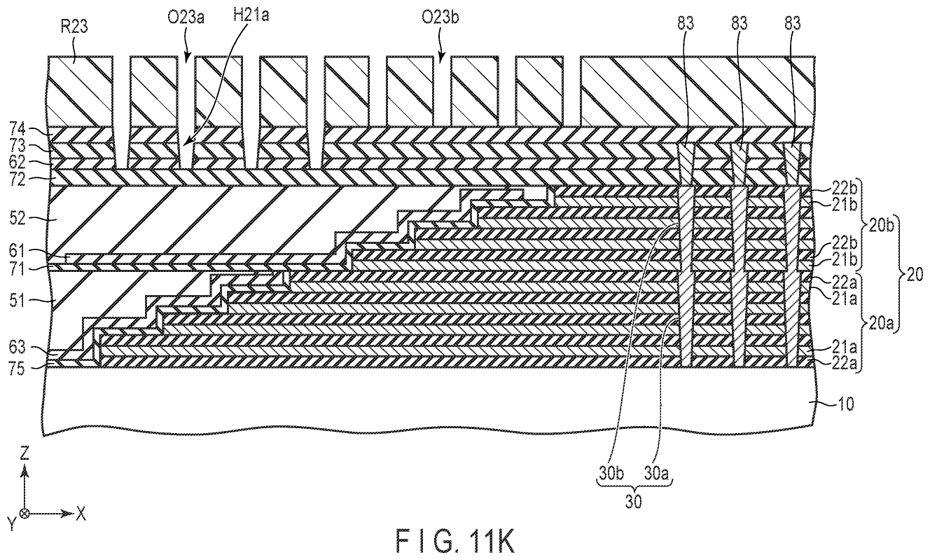

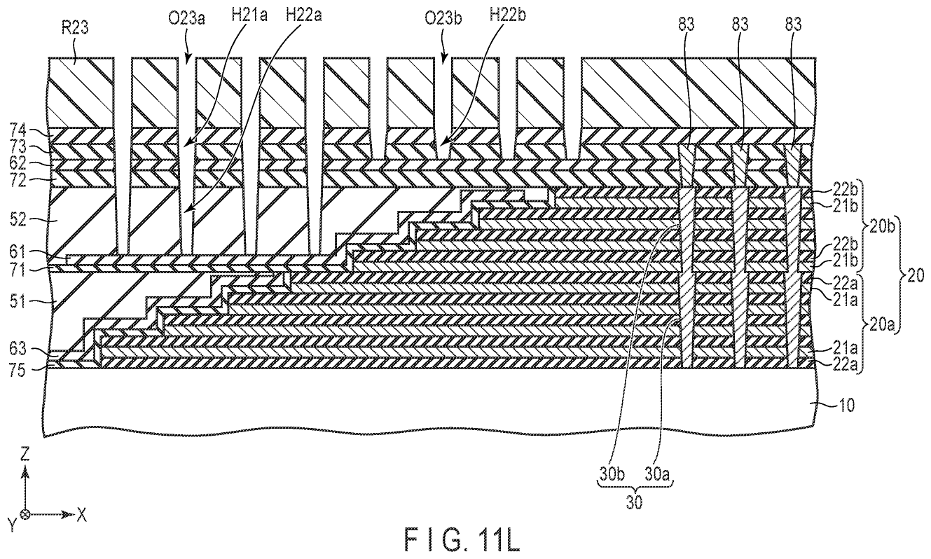

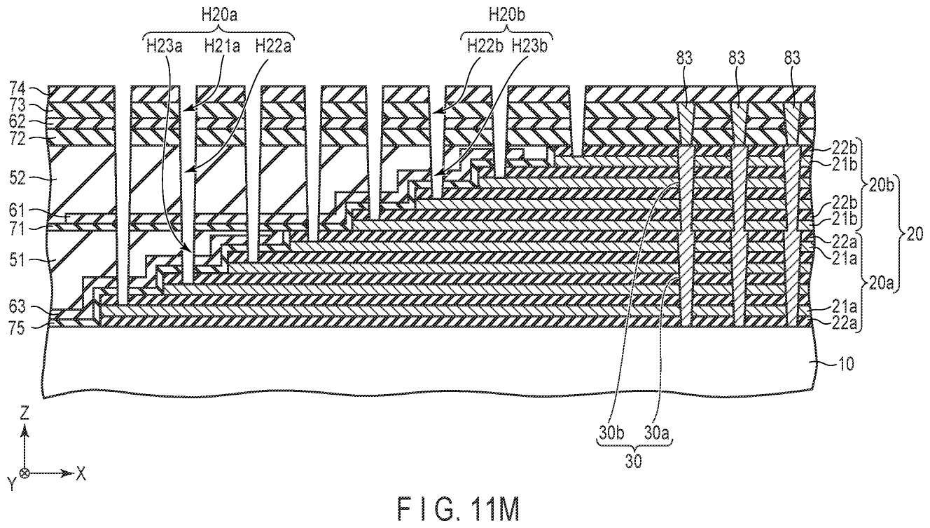

Now, a manufacturing method of the semiconductor memory device of the present embodiment will be explained with reference to cross-sectional views of FIGS. 11A to 11M and FIG. 10.

Initially, as shown in FIG. 11A, as with the process of FIG. 6A of the first embodiment, a structure including a preliminary stacked portion 20ap, a plurality of pillar portions 30a, and insulating layer 91 is formed on a semiconductor substrate 10.

Then, as shown in FIG. 11B, on the structure obtained in the process of FIG. 11A, an insulating layer 75 formed of silicon oxide, stopper insulating layer 63 formed of silicon nitride, and interlayer insulating layer 51 formed of silicon oxide are formed. Then, the insulating layer 75, stopper insulating layer 63, and interlayer insulating layer 51 are flattened using the insulating layer 91 as a stopper, and then, the insulating layer 91 is removed. As a result, the structure shown in FIG. 11B is obtained.

Then, as shown in FIG. 11C, as with the process of FIG. 6C of the first embodiment, a structure including the preliminary stacked portion 20bp, a plurality of pillar portions 30b, and insulating layer 92 is formed on the structure obtained in the process of FIG. 11B.

Then, as shown in FIG. 11D, as with the process of FIG. 6D of the first embodiment, an insulating layer 71 and a stopper insulating layer 61 are formed on the structure obtained in the process of FIG. 11C.

Then, as shown in FIG. 11E, a resist pattern R21 is formed on the stopper insulating layer 61. The resist pattern R21 covers the structure obtained in the process of FIG. 11D, from the region in which the resist pattern R11 is formed in the process of FIG. 6E in the first embodiment to the region above the end portion in the direction X of the stacked portion 20b, which is stepwise processed.

Then, as shown in FIG. 11F, by etching the stopper insulating layer 61 using the resist pattern R21 as a mask, the stopper insulating layer 61 is patterned.

Then, as shown in FIG. 11G, as with the process of FIG. 6G of the first embodiment, an interlayer insulating layer 52 is formed.

Then, as shown in FIG. 11H, as with the process of FIG. 6H of the first embodiment, a stacked body 20 including stacked portions 20a and 20b, a plurality of partition structures 40, insulating layer 72, stopper insulating layer 62, insulating layer 73, and a plurality of contacts 83 are formed.

Then, as shown in FIG. 11I, as with the process of FIG. 6I of the first embodiment, an insulating layer 74 is formed on the structure obtained in the process of FIG. 11H, and a resist pattern R22 with a plurality of openings O22a is formed on the insulating layer 74.

Then, as shown in FIG. 11J, as with the process of FIG. 6J of the first embodiment, the insulating layer 74, insulating layer 73, and stopper insulating layer 62 are etched to form a plurality of holes H21a.

Then, as shown in FIG. 11K, as with the process of FIG. 6K of the first embodiment, a resist pattern R23 with a plurality of openings O23a and a plurality of openings O23b is formed on the structure obtained in the process of FIG. 11J.

Then, as shown in FIG. 11L, as with the process of FIG. 6L of the first embodiment, a plurality of holes H22a and a plurality of holes H22b are formed.

Then, as shown in FIG. 11M, etching is performed using the resist pattern R23 and the pattern obtained in the process of FIG. 11L as masks. Specifically, under a region of the openings O23a, holes H21a, and holes H22a, the stopper insulating layer 61, insulating layer 71, interlayer insulating layer 51, stopper insulating layer 63, insulating layer 75, and insulating layer 22a are etched to form a plurality of holes H23a. Under a region of the openings O23b and holes H22b, the stopper insulating layer 62, insulating layer 72, interlayer insulating layer 52, stopper insulating layer 61, insulating layer 71, and insulating layer 22b are etched to form a plurality of holes H23b. Specifically, the stopper insulating layers 61 and 62 are etched in the common process, and then, the layer on the lower layer side of the stopper insulating layer 61 and the layer on the lower layer side of the stopper insulating layer 62 are etched in the common process. Furthermore, the stopper insulating layers 63 and 61 are etched in the common process, and then, the layer on the lower layer side of the stopper insulating layer 63 and the layer on the lower layer side of the stopper insulating layer 61 are etched in the common process.

As above, the contact holes H20a including holes H21a, H22a, and H23a and the contact holes H20b including holes H22b and H23b are obtained.

Then, as shown in FIG. 10, the contact holes H20a and H20b are filled with a conductive material, and thus, the contacts 81a, 81b, 82a, and 82b are formed in the common process.

As can be understood from the above, the basic structure of the present embodiment is similar to that of the first embodiment, and thus, the advantage similar to that of the first embodiment can be achieved.

Furthermore, in the present embodiment, in addition to the structure of the first embodiment, the stopper portion 61d of the stopper insulating layer 61 and the stopper insulating layer 63 are provided. Thus, in the present embodiment, the contacts 81a, 81b, 82a, and 82b can be further precisely formed.

### Third Embodiment

Now, a third embodiment will be explained. Note that, the basic elements are similar to those of the first embodiment, and thus, the description of the elements explained in the first embodiment will be omitted.

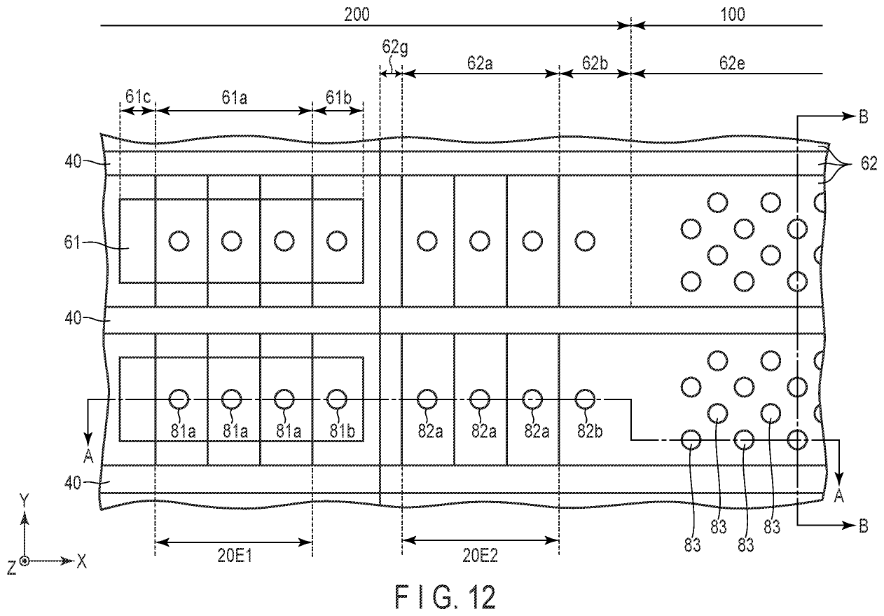

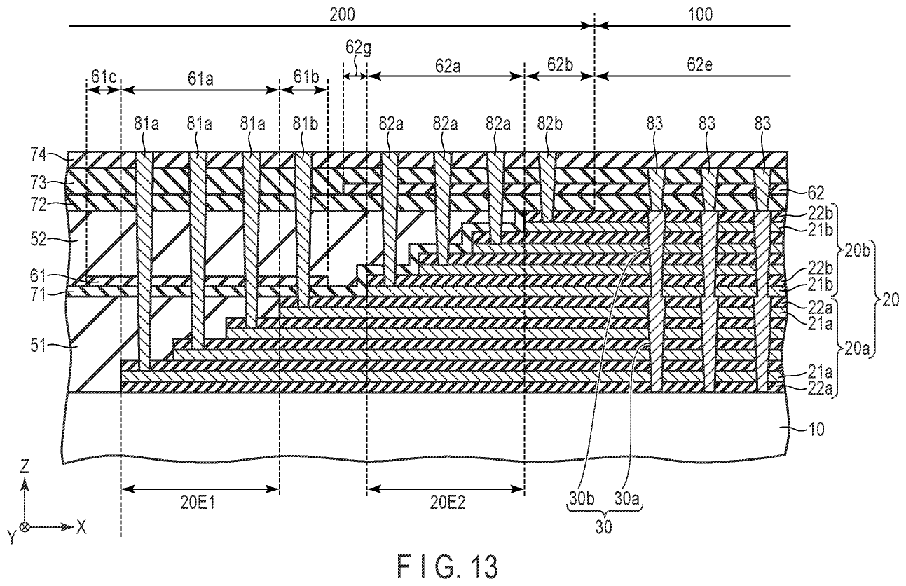

FIG. 12 is a plan pattern diagram schematically illustrating the structure of a memory region 100 and a stairs region 200 of the semiconductor memory device of the present embodiment. FIG. 13 is a schematic cross-sectional view of the structure of the memory region 100 and the stairs region 200. The cross-section taken along line A-A of FIG. 12 corresponds to FIG. 13. Note that, the cross-section taken along line B-B of FIG. 12 is similar to that of FIG. 4 of the first embodiment.

In the present embodiment, a stopper insulating layer 62 is not provided above an end portion 20E1 of a stacked portion 20a through a stopper insulating layer 61. That is, the stopper insulating layer 62 is not provided vertically above the stopper insulating layer 61. Thus, in the present embodiment, contacts 82a and 82b penetrate the stopper insulating layer 62 while contacts 81a and 81b do not penetrate the stopper insulating layer 62.

The stopper insulating layer 62 includes stopper portions 62a, 62b, 62e, and 62g. The stopper portions 62a, 62b, and 62e are similar to the stopper portions 62a, 62b, and 62e of the first embodiment. The stopper portion 62g is, as seen from the direction Z, provided outside an end portion 20E2 of the stacked portion 20b.

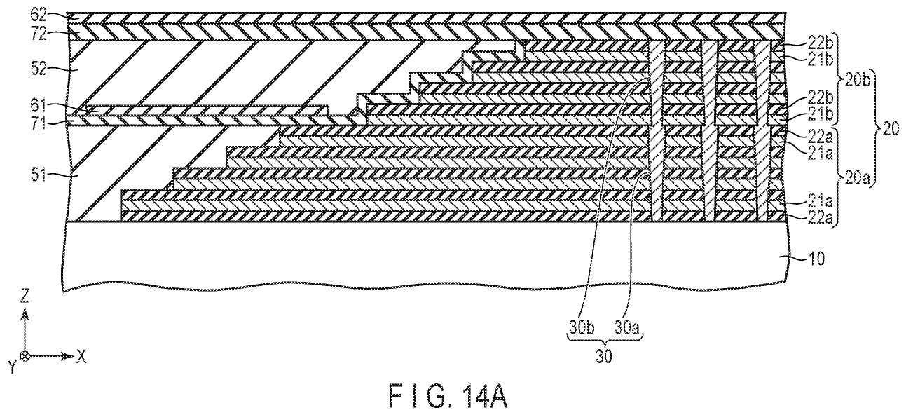

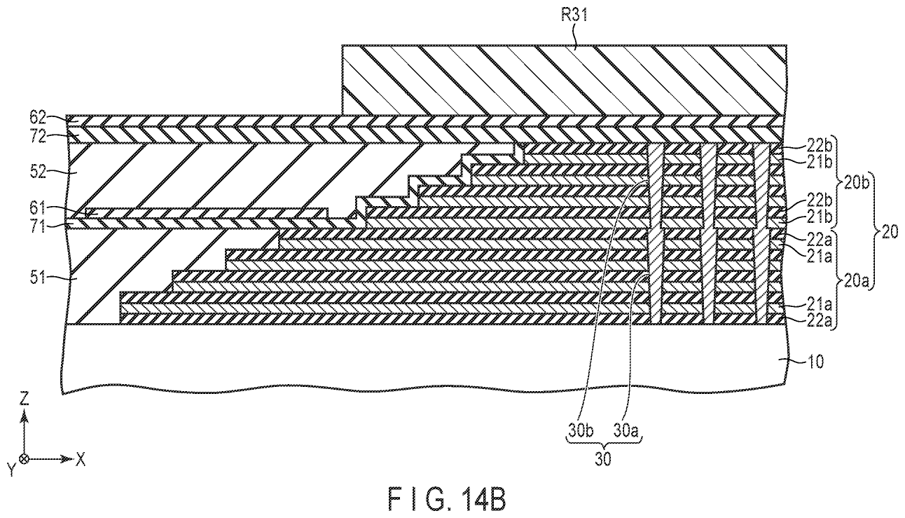

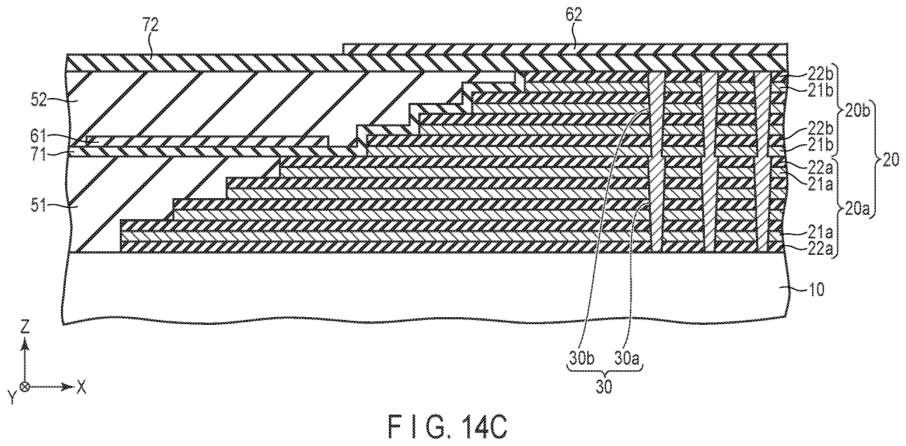

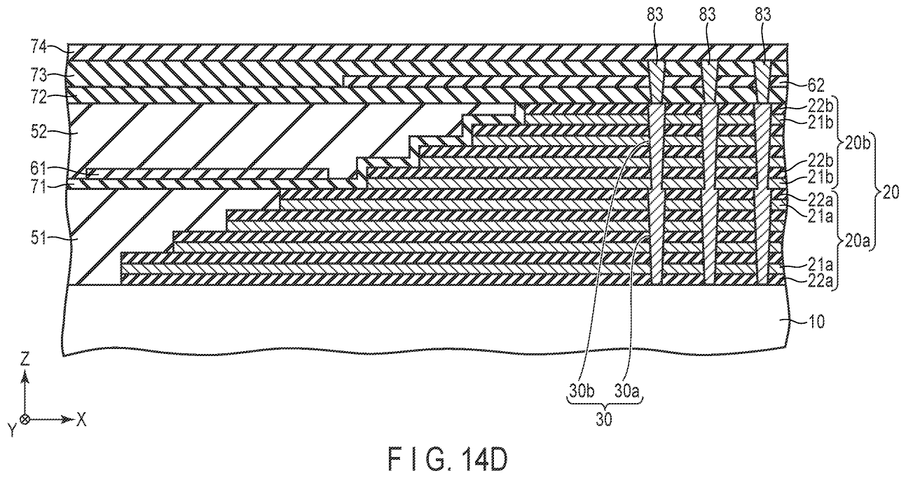

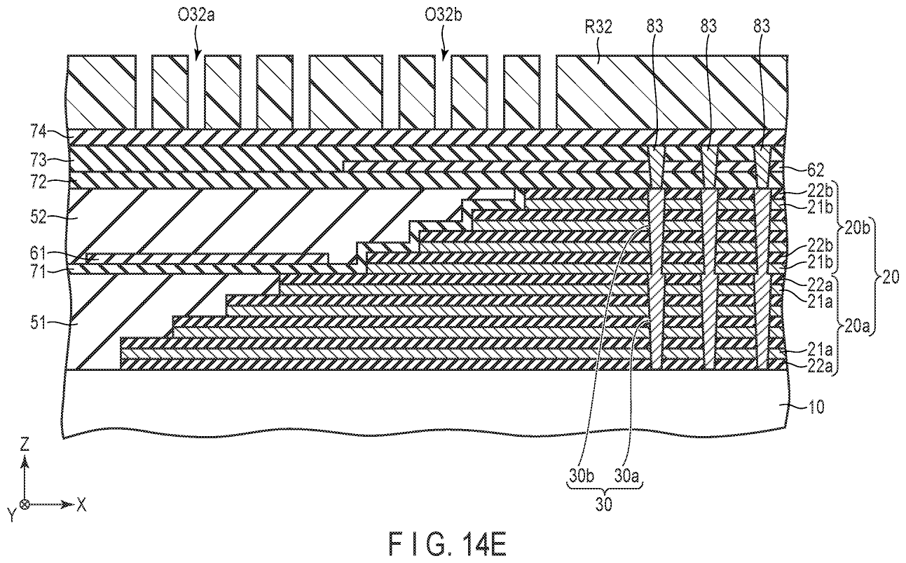

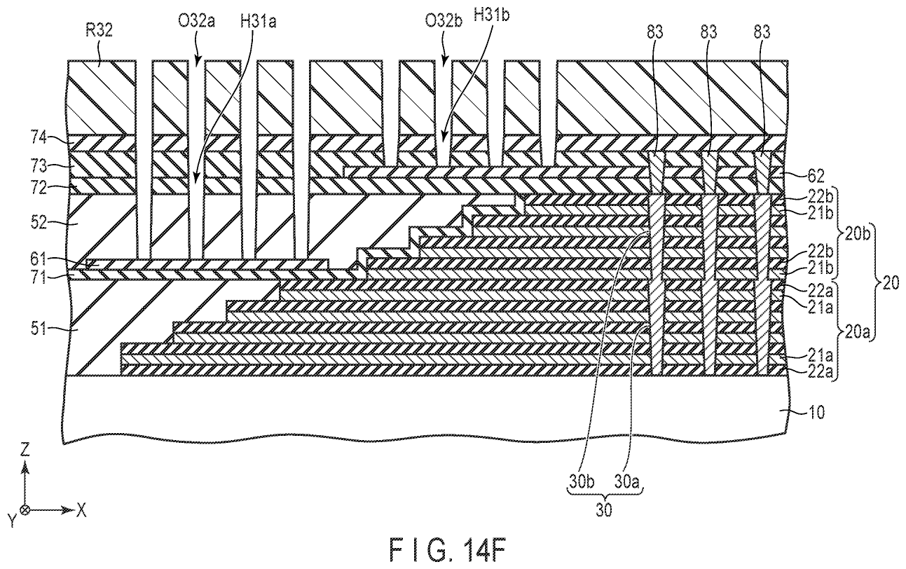

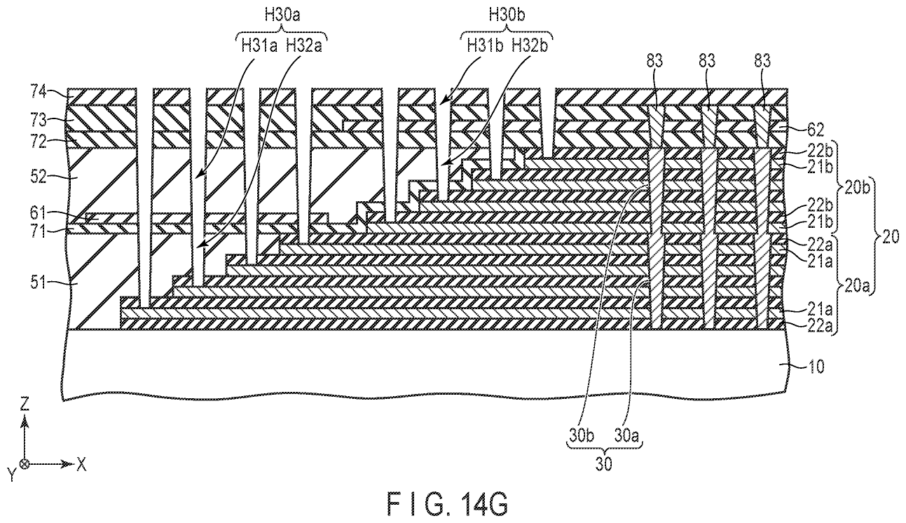

Now, a manufacturing method of the semiconductor memory device of the present embodiment will be explained with reference to cross-sectional views of FIGS. 14A to 14G, and FIG. 13.

Initially, processes similar to those shown in FIGS. 6A to 6G of the first embodiment are performed to form the structure of FIG. 6G.

Then, as shown in FIG. 14A, an insulating layer 72 is formed on the structure obtained in the process of FIG. 6G. Then, as in the process of FIG. 6H of the first embodiment, a stacked body 20 including stacked portions 20a and 20b is formed through a replacement process, and then, a plurality of partition structures 40 are formed. Then, a stopper insulating layer 62 is formed on the structure including the insulating layer 72 and the partition structure 40.

Then, as shown in FIG. 14B, a resist pattern R31 is formed on the stopper insulating layer 62.

Then, as shown in FIG. 14C, the stopper insulating layer 62 is etched using the resist pattern R31 as a mask, and thus, the stopper insulating layer 62 is patterned.

Then, as shown in FIG. 14D, the insulating layer 73 is formed on the structure obtained in the process of FIG. 14C. Then, a plurality of contact holes are formed in the insulating layer 72, stopper insulating layer 62, and insulating layer 73, and the contact holes are filled with a conductive material to form a plurality of contacts 83. Furthermore, the insulating layer 74 is formed on the structure with the contacts 83.

Then, as shown in FIG. 14E, as with the process of FIG. 6K of the first embodiment, a resist pattern R32 including openings O32a and O32b is formed on the structure obtained in the process of FIG. 14D.

Then, as shown in FIG. 14F, etching is performed using the resist pattern R32 formed in the process of FIG. 14E as a mask. Specifically, under a region of the openings O32a, the insulating layer 74, insulating layer 73, insulating layer 72, and interlayer insulating layer 52 are etched using the stopper insulating layer 61 as an etching stopper to form a plurality of holes H31a. Under a region of the openings O32b, the insulating layer 74 and the insulating layer 73 are etched using the stopper insulating layer 62 as an etching stopper to form a plurality of holes H31b. The holes H31a and H31b are formed in the common etching process.

Then, as shown in FIG. 14G, etching is performed using the resist pattern R32 and the pattern obtained in the process of FIG. 14F as masks. Specifically, under a region of the openings O32a and the holes H31a, the stopper insulating layer 61, insulating layer 71, interlayer insulating layer 51, and insulating layer 22a are etched to form a plurality of holes H32a. Under a region of the openings O32b and the holes H31b, the stopper insulating layer 62, insulating layer 72, interlayer insulating layer 52, insulating layer 71, and insulating layer 22b are etched to form a plurality of holes H32b. Specifically, the stopper insulating layers 61 and 62 are etched in the common process, and then, the layer on the lower layer side of the stopper insulating layer 61 and the layer on the lower layer side of the stopper insulating layer 62 are etched in the common process.

Thus, contact holes H30a including holes H31a and H32a and contact holes H30b including holes H31b and H32b are obtained.

Then, as shown in FIG. 13, the contact holes H30a and H30b are filled with a conductive material, and thus, contacts 81a, 81b, 82a, and 82b are formed in the common process.

As can be understood from the above, the basic structure of the present embodiment is similar to that of the first embodiment, and thus, the advantage similar to that of the first embodiment can be achieved.

Furthermore, in the present embodiment, the stopper insulating layer 62 is not provided vertically above the stopper insulating layer 61, and the contacts 81a, 81b, 82a, and 82b penetrates only one of the stopper insulating layers 61 and 62. Thus, a lithography process to form the contact holes H30a and H30b may be performed once in FIG. 14E. Thus, in the present embodiment, an alignment shift shown in FIGS. 7 and 8 of the first embodiment does not occur. That is, as seen from the direction Z, the center of the upper end of the contact 81a and the center of the lower end of the contact 81a are substantially identical to each other. Thus, in the present embodiment, the contacts 81a, 81b, 82a, and 82b can be further precisely formed.

### Fourth Embodiment

Now, a fourth embodiment will be explained. Note that, the basic elements are similar to those of the first and third embodiments, and thus, the description of the elements explained in the first and third embodiments will be omitted.

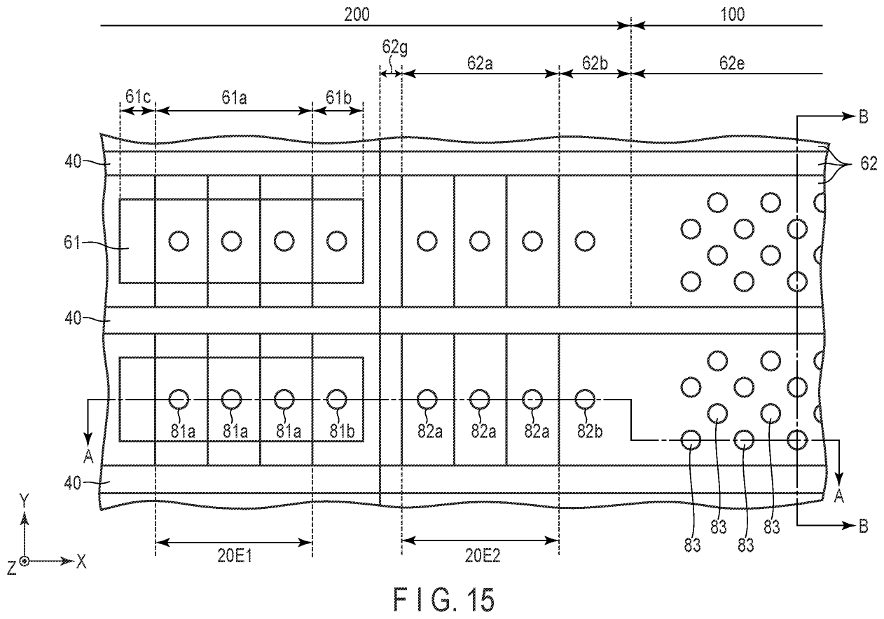

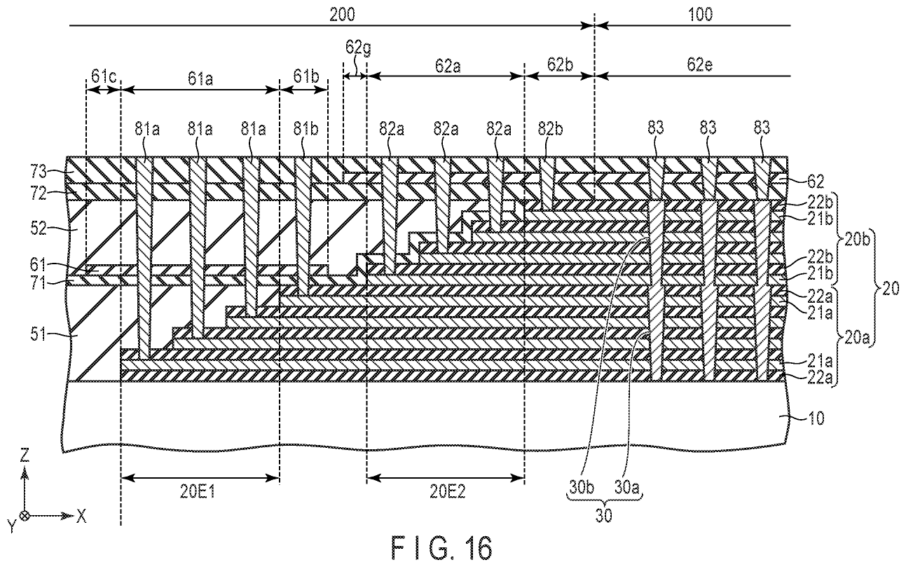

FIG. 15 is a plan pattern diagram schematically illustrating the structure of a memory region 100 and a stairs region 200 of the semiconductor memory device of the present embodiment. FIG. 16 is a schematic cross-sectional view of the structure of the memory region 100 and the stairs region 200. The cross-section taken along line A-A of FIG. 15 corresponds to FIG. 16. Note that, the cross-section taken along line B-B of FIG. 15 is similar to that of FIG. 4 of the first embodiment.

In the aforementioned first, second, and third embodiments, the level of the upper end of the contact 83 in the height direction is lower than the level of the upper ends of the contacts 81a, 81b, 82a, and 82b in the height direction; however, in the present embodiment, the level of the upper end of the contact 83 in the height direction is substantially the same as the level of the upper ends of the contacts 81a, 81b, 82a, and 82b in the height direction.

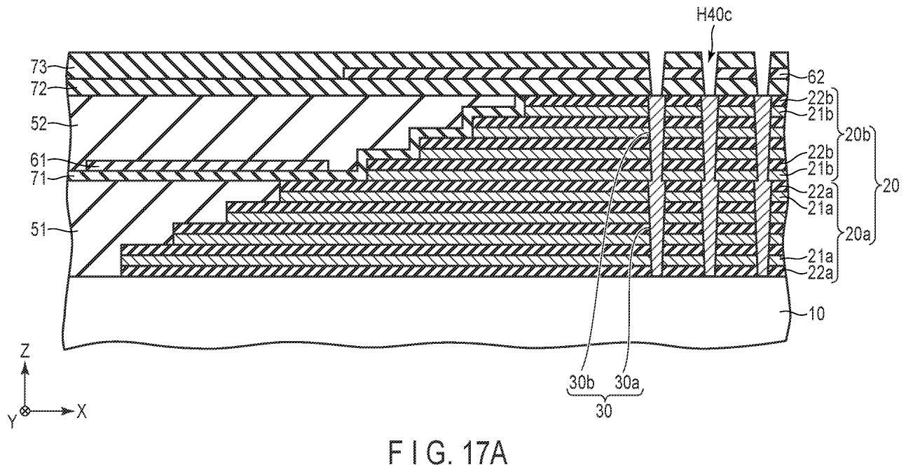

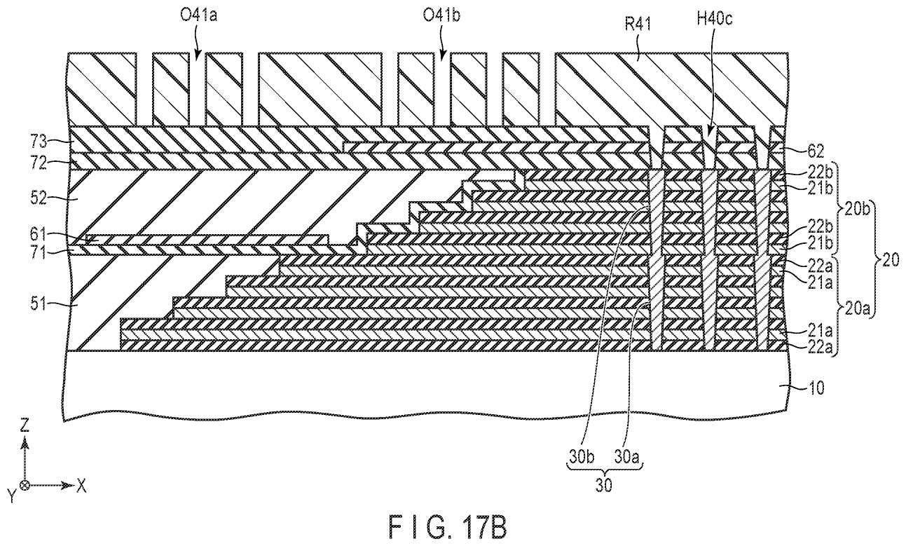

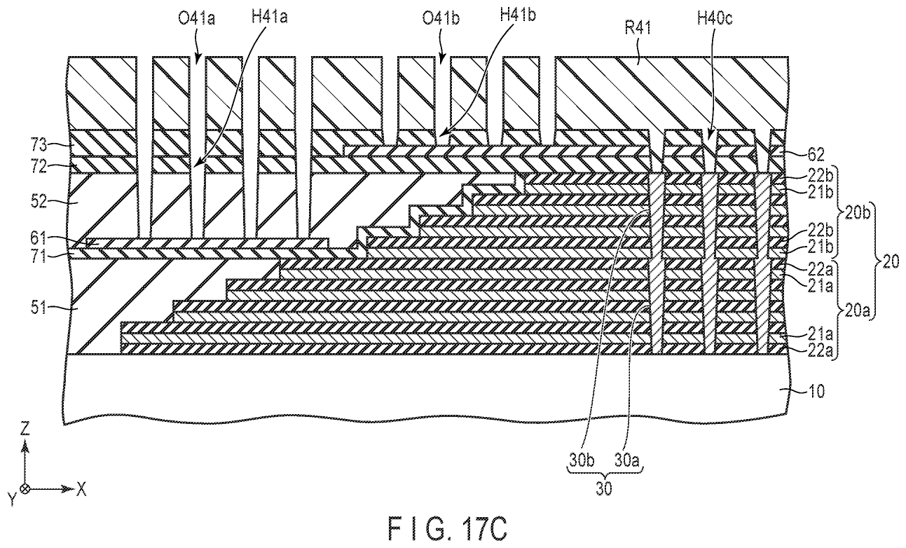

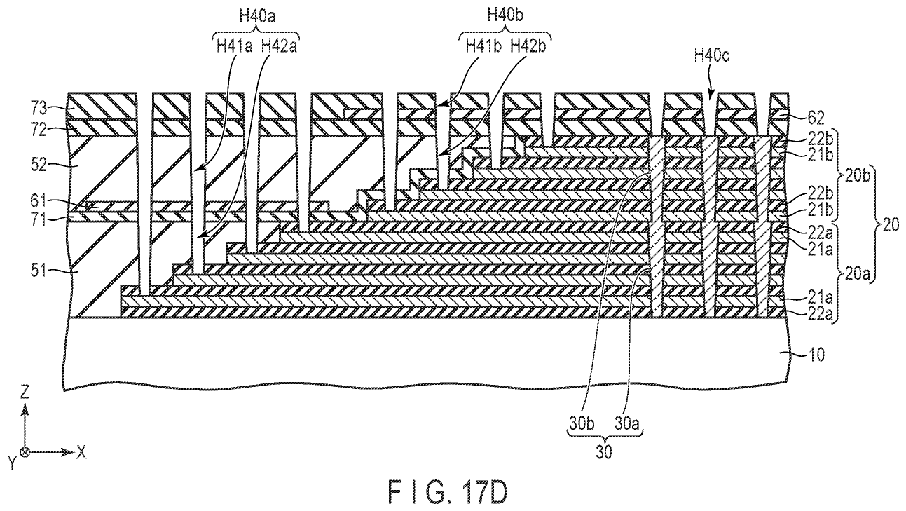

Now, a manufacturing method of the semiconductor memory device of the present embodiment will be explained with reference to cross-sectional views of FIGS. 17A to 17D and FIG. 16.

Initially, processes similar to those of FIGS. 6A to 6G of the first embodiment are performed to form a structure as shown in FIG. 6G. Then, processes similar to those of FIGS. 14A to 14C of the third embodiment are performed to form a structure as shown in FIG. 14C.

Then, as shown in FIG. 17A, an insulating layer 73 is formed on the structure obtained in the process of FIG. 14C, and then, a resist pattern with openings (which is not shown) above the pillar structures 30 is formed on the insulating layer 73. Furthermore, the insulating layer 73, stopper insulating layer 62, and insulating layer 72 are etched using the resist pattern as a mask. As a result, contact holes H40c reaching the upper surfaces of the pillar structures 30 are formed.

Then, as shown in FIG. 17B, as in the process of FIG. 14E of the third embodiment, a resist pattern R41 with openings O41a and O41b is formed on the structure obtained in the process of FIG. 17A.

Then, as shown in FIG. 17C, etching is performed using the resist pattern R41 formed in the process of FIG. 17B as a mask. Specifically, under the openings O41a, the insulating layer 73, insulating layer 72, and interlayer insulating layer 52 are etched using the stopper insulating layer 61 as an etching stopper to form a plurality of holes H41a. Under the openings O41b, the insulating layer 73 is etched using the stopper insulating layer 62 as an etching stopper to form a plurality of holes H41b. The holes H41a and H41b are formed in the common etching process.

Then, as shown in FIG. 17D, etching is performed using the resist pattern R41 and the pattern obtained in the process of FIG. 17C as masks. Specifically, under the openings O41a and the holes H41a, the stopper insulating layer 61, insulating layer 71, interlayer insulating layer 51, and insulating layer 22a are etched to form a plurality of holes H42a. Under the openings O41b and the holes H41b, the stopper insulating layer 62, insulating layer 72, interlayer insulating layer 52, insulating layer 71, and insulating layer 22b are etched to form a plurality of holes H42b. Specifically, the stopper insulating layers 61 and 62 are etched in the common process, and then, the layer on the lower layer side of the stopper insulating layer 61 and the layer on the lower layer side of the stopper insulating layer 62 are etched in the common process. Then, the resist pattern R41 is removed.

As above, the contact holes H40a including holes H41a and H42a, the contact holes H40b including holes H41b and H42b, and the contact holes H40c are obtained.

Then, as shown in FIG. 16, the contact holes H40a, H40b, and H40c are filled with a conductive material, and thus, the contacts 81a, 81b, 82a, 82b, and 83 are formed in the common process.

As can be understood from the above, the basic structure of the present embodiment is similar to those of the first and third embodiments, and thus, the advantage similar to those of the first and third embodiments can be achieved.

Furthermore, in the present embodiment, the contacts 81a, 81b, 82a, 82b, and 83 can be formed in the common process in the contact holes H40a, H40b, and H40c, and the level of the upper ends of the contacts 81a, 81b, 82a, 82b, and 83 can be set substantially the same.

The structures of above-described first to fourth embodiments may be arbitrarily combined. For example, a structure of the third embodiment (the stopper insulating layer 62 is not provided vertically above the stopper insulating layer 61) may be applied to the structure of the second embodiment. Furthermore, a structure of the fourth embodiment (the level of the contact 83 in the height direction is substantially the same as the level of the contacts 81a, 81b, 82a, and 82b in the height direction) may be applied to the structure of the first or second embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a stacked body including a first stacked portion including a plurality of first conductive layers stacked to be apart from each other in a first direction and having a first end portion stepwise processed along a second direction crossing the first direction, and a second stacked portion provided on an upper layer side of the first stacked portion, including a plurality of second conductive layers stacked to be apart from each other in the first direction, and having a second end portion arranged beside the first end portion in the second direction and stepwise processed along the second direction;
a plurality of pillar structures each including a semiconductor layer extending along the first direction in the stacked body;
a first interlayer insulating layer covering the first end portion;
a second interlayer insulating layer provided on an upper layer side of the first interlayer insulating layer and covering the second end portion;
a first stopper insulating layer provided at least between the first interlayer insulating layer and the second interlayer insulating layer and above the first end portion, including a first portion extending flat along a plane perpendicular to the first direction above the first end portion throughout the first end portion in the second direction, and formed of a material with a main component which is different from that of a material of the first interlayer insulating layer and that of a material of the second interlayer insulating layer;
a second stopper insulating layer including at least a first portion provided on an upper layer side of the second interlayer insulating layer and above the second end portion, and formed of a material with a main component which is different from that of the material of the first interlayer insulating layer and that of the material of the second interlayer insulating layer;
a plurality of first contacts penetrating the second interlayer insulating layer, the first portion of the first stopper insulating layer and the first interlayer insulating layer, and connected to different first conductive layers, respectively, of the plurality of first conductive layers; and
a plurality of second contacts penetrating the first portion of the second stopper insulating layer and the second interlayer insulating layer, and connected to different second conductive layers, respectively, of the plurality of second conductive layers.

2. The device of claim 1, further comprising a plurality of third contacts penetrating a second portion of the second stopper insulating layer provided to be opposed to an uppermost surface of the second stacked portion in the first direction, and each connected to the semiconductor layer of a respective pillar structure of the plurality of pillar structures.

3. The device of claim 1, further comprising a third stopper insulating layer including a first portion provided along the first end portion, and formed of a material with a main component which is different from that of the material of the first interlayer insulating layer and that of the material of the second interlayer insulating layer, wherein
the first stopper insulating layer further includes a second portion provided along the second end portion,
the plurality of first contacts further penetrate the first portion of the third stopper insulating layer, and
the plurality of second contacts further penetrate the second portion of the first stopper insulating layer.

4. The device of claim 1, wherein
the second stopper insulating layer is not provided above the first end portion through the first stopper insulating layer.

5. The device of claim 1, wherein
the plurality of first contacts further penetrate a third portion of the second stopper insulating layer provided on an upper layer side of the second interlayer insulating layer and above the first end portion.

6. The device of claim 1, further comprising one contact penetrating the second interlayer insulating layer and a portion of the first stopper insulating layer provided to be opposed to an uppermost surface of the first stacked portion in the first direction, without penetrating the first interlayer insulating layer, and connected to an uppermost first conductive layer of the plurality of first conductive layers.

7. The device of claim 1, further comprising another one contact penetrating a portion of the second stopper insulating layer provided to be opposed to an uppermost surface of the second stacked portion in the first direction, without penetrating the second interlayer insulating layer, and connected to an uppermost second conductive layer of the plurality of second conductive layers.

8. The device of claim 1, wherein
the first stopper insulating layer and the second stopper insulating layer are formed of a same material.

9. The device of claim 1, wherein
a level of upper ends of the plurality of first contacts in a height direction and a level of upper ends of the plurality of second contacts in the height direction are substantially identical to each other.

10. The device of claim 2, wherein
a level of upper ends of the plurality of first contacts in a height direction, a level of upper ends of the plurality of second contacts in the height direction, and a level of upper ends of the plurality of third contacts in the height direction are substantially identical to one another.

11. A semiconductor memory device comprising:
a stacked body including a first stacked portion including a plurality of first conductive layers stacked to be apart from each other in a first direction and having a first end portion stepwise processed along a second direction crossing the first direction, and a second stacked portion provided on an upper layer side of the first stacked portion, including a plurality of second conductive layers stacked to be apart from each other in the first direction, and having a second end portion arranged beside the first end portion in the second direction and stepwise processed along the second direction;
a plurality of pillar structures each including a semiconductor layer extending along the first direction in the stacked body;
a first interlayer insulating layer covering the first end portion;
a second interlayer insulating layer provided on an upper layer side of the first interlayer insulating layer and covering the second end portion;
a first stopper insulating layer provided at least between the first interlayer insulating layer and the second interlayer insulating layer and above the first end portion, including a first portion extending flat along a plane perpendicular to the first direction above the first end portion throughout the first end portion in the second direction, and formed of a material with a main component which is different from that of a material of the first interlayer insulating layer and that of a material of the second interlayer insulating layer;
a plurality of first contacts penetrating the second interlayer insulating layer, the first portion of the first stopper insulating layer and the first interlayer insulating layer, and connected to different first conductive layers, respectively, of the plurality of first conductive layers; and
a plurality of second contacts penetrating the second interlayer insulating layer, and connected to different second conductive layers, respectively, of the plurality of second conductive layers.

12. The device of claim 11, further comprising one contact penetrating the second interlayer insulating layer and a portion of the first stopper insulating layer provided to be opposed to an uppermost surface of the first stacked portion in the first direction, without penetrating the first interlayer insulating layer, and connected to an uppermost first conductive layer of the plurality of first conductive layers.

13. The device of claim 11, wherein
the first stopper insulating layer further includes a second portion provided along the second end portion, and
the plurality of second contacts further penetrate the second portion of the first stopper insulating layer.

14. The device of claim 13, further comprising a second stopper insulating layer including a first portion provided along the first end portion, and formed of a material with a main component which is different from that of the material of the first interlayer insulating layer and that of the material of the second interlayer insulating layer, wherein
the plurality of first contacts further penetrate the first portion of the second stopper insulating layer.

15. The device of claim 14, wherein
the first stopper insulating layer and the second stopper insulating layer are formed of a same material.

16. The device of claim 11, wherein
the first stopper insulating layer is not provided between the first stacked portion and the second stacked portion.

17. A semiconductor memory device comprising:
a stacked body including a first stacked portion including a plurality of first conductive layers stacked to be apart from each other in a first direction and having a first end portion stepwise processed along a second direction crossing the first direction, and a second stacked portion provided on an upper layer side of the first stacked portion, including a plurality of second conductive layers stacked to be apart from each other in the first direction, and having a second end portion arranged beside the first end portion in the second direction and stepwise processed along the second direction;
a plurality of pillar structures each including a semiconductor layer extending along the first direction in the stacked body;
a first interlayer insulating layer covering the first end portion;
a second interlayer insulating layer provided on an upper layer side of the first interlayer insulating layer and covering the second end portion;
a stopper insulating layer including at least a first portion provided on an upper layer side of the second interlayer insulating layer and above the second end portion and a second portion provided to be opposed to an uppermost surface of the second stacked portion in the first direction, without including a portion provided above the first end portion, and formed of a material with a main component which is different from that of a material of the first interlayer insulating layer and that of a material of the second interlayer insulating layer;
a plurality of first contacts penetrating the second interlayer insulating layer and the first interlayer insulating layer, and connected to different first conductive layers, respectively, of the plurality of first conductive layers;
a plurality of second contacts penetrating the first portion of the stopper insulating layer and the second interlayer insulating layer, and connected to different second conductive layers, respectively, of the plurality of second conductive layers; and
a plurality of third contacts penetrating the second portion of the stopper insulating layer, and each connected to the semiconductor layer of a respective pillar structure of the plurality of pillar structures.

18. The device of claim 17, further comprising one contact penetrating the second portion of the stopper insulating layer, without penetrating the second interlayer insulating layer, and connected to an uppermost second conductive layer of the plurality of second conductive layers.

19. The device of claim 17, wherein
a level of upper ends of the plurality of third contacts in a height direction is lower than a level of upper ends of the plurality of first contacts in the height direction and a level of upper ends of the plurality of second contacts in the height direction.

20. The device of claim 17, wherein
a level of upper ends of the plurality of third contacts in a height direction is substantially identical to a level of upper ends of the plurality of first contacts in the height direction and a level of upper ends of the plurality of second contacts in the height direction.
